(19) United States
(12) Patent Application Publication
(10) Pub. No.: US 2024/0063237 A1
(43) Pub. Date: Feb. 22, 2024

(54) SOLID-STATE IMAGING DEVICE AND ELECTRONIC EQUIPMENT

(71) Applicant: SONY SEMICONDUCTOR SOLUTIONS CORPORATION, KANAGAWA (JP)

(72) Inventor: TAKURO MURASE, KANAGAWA (JP)

(21) Appl. No.: 18/260,989

(22) PCT Filed: Jan. 7, 2022
(86) PCT No.: PCT/JP2022/000295

§ 371 Date: Jul. 11, 2023

(30) Foreign Application Priority Data
Jan. 20, 2021 (JP) 2021-007008

(51) Int. Cl. H01L 27/146; H01L 23/00

(52) U.S. Cl. CPC H01L 27/14623; H01L 27/14636; H01L 27/14634; H01L 24/05; H01L 24/08; H01L 27/14641; H01L 2224/05647; H01L 2224/08145

(57) ABSTRACT

PLS is further suppressed. A solid-state imaging device includes: a first semiconductor substrate including a first semiconductor layer provided with a plurality of photoelectric conversion units that performs photoelectric conversion, and a first wiring layer provided on a surface side opposite to a light incident surface of the first semiconductor layer; a second semiconductor substrate including a second semiconductor layer provided with a charge holding unit that holds signal charge generated in the photoelectric conversion unit and a second wiring layer provided on one surface side of the second semiconductor layer, and overlapped with and bonded to the first semiconductor substrate such that the second wiring layer is positioned between the first wiring layer and the second semiconductor layer; and a light shielding layer provided in at least one of the first wiring layer or the second wiring layer at a position facing the charge holding unit in a thickness direction.

### TECHNICAL FIELD

The present technology (technology according to the present disclosure) relates to a solid-state imaging device and electronic equipment, and particularly relates to a solid-state imaging device and electronic equipment including a charge holding unit.

### BACKGROUND ART

Conventionally, a charge holding unit such as a floating diffusion has been used as a memory that temporarily holds signal charge photoelectrically converted by a photoelectric conversion unit such as a photodiode. However, in a case where signal charge is temporarily held in the floating diffusion, parasitic light sensitivity (PLS) may become a problem due to stray light. More specifically, when stray light enters the floating diffusion, photoelectric conversion is also performed inside the floating diffusion to generate signal charge, and the signal charge is erroneously detected. Therefore, in the following Patent Document 1, the position of the floating diffusion is separated from the optical center of the pixel in order to better inhibit stray light as compared with the related art.

### CITATION LIST

### Patent Document

Patent Document 1: Japanese Patent Application Laid-Open No. 2017-168566

### SUMMARY OF THE INVENTION

### Problems to be Solved by the Invention

An object of the present technology is to provide a solid-state imaging device and electronic equipment capable of further suppressing PLS.

### Solutions to Problems

According to an aspect of the present technology, there is provided a solid-state imaging device including: a first semiconductor substrate including a first semiconductor layer provided with a plurality of photoelectric conversion units that performs photoelectric conversion, and a first wiring layer provided on a surface side opposite to a light incident surface of the first semiconductor layer; a second semiconductor substrate including a second semiconductor layer provided with a charge holding unit that holds signal charge generated in the photoelectric conversion unit and a second wiring layer provided on one surface side of the second semiconductor layer, and overlapped with and bonded to the first semiconductor substrate such that the second wiring layer is positioned between the first wiring layer and the second semiconductor layer; and a light shielding layer provided in at least one of the first wiring layer or the second wiring layer at a position facing the charge holding unit in a thickness direction.

According to another aspect of the present technology, there is provided electronic equipment including the solid-state imaging device and an optical system that forms an image of image light from a subject on the solid-state imaging device.

According to another aspect of the present technology, there is provided a solid-state imaging device including: a first semiconductor layer including a first region including a first semiconductor material and a second region including a second semiconductor material of which a quantum efficiency indicating a probability that photons are converted into electrons is lower than that of the first semiconductor material, and including a photoelectric conversion unit that performs photoelectric conversion and a charge holding unit that holds signal charge generated by the photoelectric conversion unit, in which the photoelectric conversion unit is provided in a region including at least the first region out of the first region and the second region, and the charge holding unit is provided in the second region.

According to another aspect of the present technology, there is provided electronic equipment including the solid-state imaging device and an optical system that forms an image of image light from a subject on the solid-state imaging device.

### BRIEF DESCRIPTION OF DRAWINGS

FIG. 1 is a chip layout diagram showing a configuration example of a solid-state imaging device according to a first embodiment of the present technology.

FIG. 2 is a block diagram showing a configuration example of the solid-state imaging device according to the first embodiment of the present technology.

FIG. 3 is an equivalent circuit diagram showing a configuration example of a pixel.

FIG. 4A is a longitudinal sectional view showing a sectional structure taken along line A-A of FIG. 1.

FIG. 4B is a transverse sectional view showing a relative relationship between respective components when FIG. 4A is viewed in a cross-sectional view in a second surface.

FIG. 4C is a transverse sectional view showing a relative relationship between respective components when FIG. 4A is viewed in a cross-sectional view in a sixth surface.

FIG. 5 is a longitudinal sectional view showing a main part of FIG. 4A.

FIG. 6 is a timing chart for explaining a reset operation of a floating diffusion and a light absorption unit of the solid-state imaging device according to the first embodiment of the present technology.

FIG. 7 is a transverse sectional view showing another aspect of a relative relationship between respective components of FIG. 4C.

FIG. 8 is a longitudinal sectional view showing a main part of a solid-state imaging device according to Modification Example 1 of the first embodiment of the present technology.

FIG. 9A is a longitudinal sectional view showing a main part of a solid-state imaging device according to Modification Example 2 of the first embodiment of the present technology.

FIG. 9B is a transverse sectional view showing a relative relationship between respective components when FIG. 9A is viewed in a cross-sectional view in the sixth surface.

FIG. 10 is a timing chart for explaining a reset operation of the floating diffusion and the light absorption unit of the solid-state imaging device according to Modification Example 2 of the first embodiment of the present technology.

FIG. 11 is a longitudinal sectional view showing a main part of another solid-state imaging device according to Modification Example 2 of the first embodiment of the present technology.

FIG. 12A is a longitudinal sectional view showing a main part of a solid-state imaging device according to Modification Example 3 of the first embodiment of the present technology.

FIG. 12B is a transverse sectional view showing a relative relationship between respective components when FIG. 12A is viewed in a cross-sectional view in the sixth surface.

FIG. 13A is a longitudinal sectional view showing a main part of a solid-state imaging device according to a second embodiment of the present technology.

FIG. 13B is a transverse sectional view showing a relative relationship between respective components when FIG. 13A is viewed in a cross-sectional view in the second surface.

FIG. 13C is a transverse sectional view showing a relative relationship between respective components when FIG. 13A is viewed in a cross-sectional view in the sixth surface.

FIG. 14 is a longitudinal sectional view showing a main part of another solid-state imaging device according to the second embodiment of the present technology.

FIG. 15A is a longitudinal sectional view showing a main part of a solid-state imaging device according to Modification Example 1 of the second embodiment of the present technology.

FIG. 15B is a transverse sectional view showing a relative relationship between respective components when FIG. 15A is viewed in a cross-sectional view in the second surface.

FIG. 16 is a longitudinal sectional view showing a main part of another solid-state imaging device according to Modification Example 1 of the second embodiment of the present technology.

FIG. 17A is a longitudinal sectional view showing a main part of a solid-state imaging device according to Modification Example 2 of the second embodiment of the present technology.

FIG. 17B is a transverse sectional view showing a relative relationship between respective components when FIG. 17A is viewed in a cross-sectional view in the second surface.

FIG. 18 is a transverse sectional view showing another aspect of a relative relationship between respective components of FIG. 17B.

FIG. 19 is a longitudinal sectional view showing a main part of another solid-state imaging device according to Modification Example 2 of the second embodiment of the present technology.

FIG. 20 is a longitudinal sectional view showing a main part of a solid-state imaging device according to Modification Example 3 of the second embodiment of the present technology.

FIG. 21 is a longitudinal sectional view showing a main part of another solid-state imaging device according to Modification Example 3 of the second embodiment of the present technology.

FIG. 22 is a longitudinal sectional view showing a main part of a solid-state imaging device according to Modification Example 4 of the second embodiment of the present technology.

FIG. 23 is a longitudinal sectional view showing a main part of another solid-state imaging device according to Modification Example 4 of the second embodiment of the present technology.

FIG. 24A is a longitudinal sectional view showing a main part of a solid-state imaging device according to Modification Example 5 of the second embodiment of the present technology.

FIG. 24B is a transverse sectional view showing a relative relationship between respective components when FIG. 24A is viewed in a cross-sectional view in the second surface.

FIG. 24C is a transverse sectional view showing a relative relationship between respective components when FIG. 24A is viewed in a cross-sectional view in the sixth surface.

FIG. 25A is a longitudinal sectional view showing a main part of another solid-state imaging device according to Modification Example 5 of the second embodiment of the present technology.

FIG. 25B is a transverse sectional view showing a relative relationship between respective components when FIG. 25A is viewed in a cross-sectional view in the second surface.

FIG. 26A is a longitudinal sectional view showing a main part of a solid-state imaging device according to Modification Example 6 of the second embodiment of the present technology.

FIG. 26B is a transverse sectional view showing a relative relationship between respective components when FIG. 26A is viewed in a cross-sectional view in the second surface.

FIG. 26C is a transverse sectional view showing a relative relationship between respective components when FIG. 26A is viewed in a cross-sectional view in the sixth surface.

FIG. 27A is a longitudinal sectional view showing a main part of another solid-state imaging device according to Modification Example 6 of the second embodiment of the present technology.

FIG. 27B is a transverse sectional view showing a relative relationship between respective components when FIG. 27A is viewed in a cross-sectional view in the second surface.

FIG. 28 is a longitudinal sectional view showing a main part of a solid-state imaging device according to a third embodiment of the present technology.

FIG. 29 is a block diagram showing a configuration example of distance image equipment according to a fourth embodiment using the solid-state imaging device of the present technology.

### MODE FOR CARRYING OUT THE INVENTION

A preferred embodiment for implementing the present technology will be described below with reference to the drawings. Note that the embodiment hereinafter described shows an example of the representative embodiment of the present technology, and the scope of the present technology is not narrowed by the example.

In the following drawings, the same or similar parts are denoted by the same or similar reference numerals. It should be noted that the drawings are schematic, and a relationship between a thickness and planar dimensions, a ratio of the thicknesses between layers, and the like are different from actual ones. Therefore, specific thicknesses and dimensions should be determined in consideration of the following description. Furthermore, it is needless to say that the drawings include portions having different dimensional relationships and ratios.

Furthermore, the first to fourth embodiments shown below exemplify devices and methods for embodying the technical idea of the present technology, and the materials, shapes, structures, arrangements, and the like of the components are not specified as follows. Various modifications can be made to the technical idea of the present technology within the technical scope defined by the claims described in the claims.

The description will be made in the following order.
1. First Embodiment
2. Modification Example 1 of First Embodiment
3. Modification Example 2 of First Embodiment
4. Modification Example 3 of First Embodiment
6. Second Embodiment
7. Modification Example 1 of Second Embodiment
8. Modification Example 2 of Second Embodiment
9. Modification Example 3 of Second Embodiment
10. Modification Example 4 of Second Embodiment
11. Modification Example 5 of Second Embodiment
12. Modification Example 6 of Second Embodiment
13. Third Embodiment
14. Fourth Embodiment

### First Embodiment

### <Entire Configuration of Solid-State Imaging Device>

The present embodiment will describe an example in which the present technology is applied to a solid-state imaging device 1 that is a back illumination type complementary metal oxide semiconductor (CMOS) image sensor. More specifically, the present embodiment will describe an example in which the present technology is applied to a distance image sensor that measures a distance by a time-of-flight (ToF) method, which is an example of the solid-state imaging device 1.

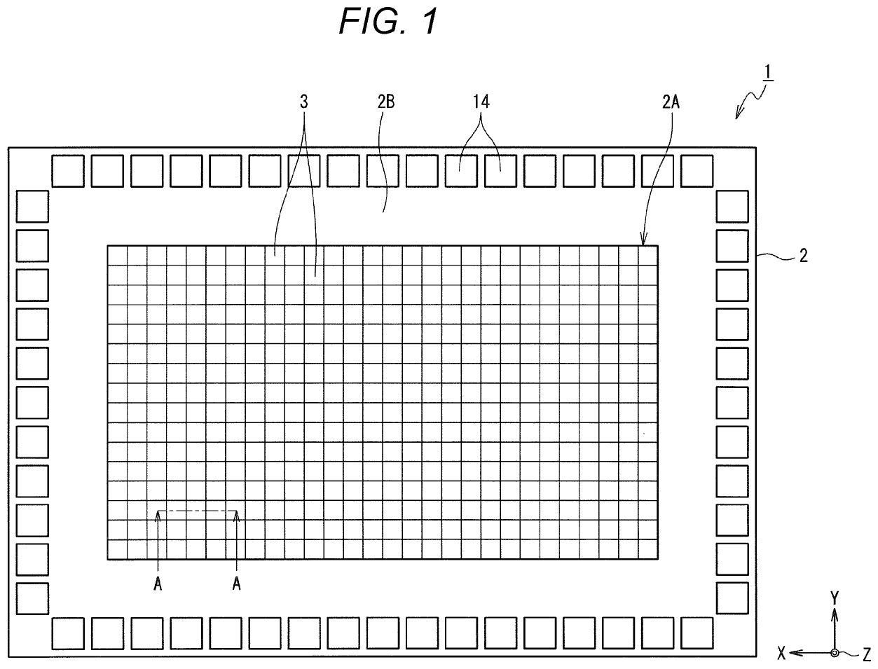

As shown in FIG. 1, a solid-state imaging device 1 according to the first embodiment of the present technology mainly includes a semiconductor chip 2 having a rectangular two-dimensional planar shape in plan view. That is, the solid-state imaging device 1 as a distance image sensor is mounted on the semiconductor chip 2. The semiconductor chip 2 includes a rectangular pixel region 2A arranged in a central portion, and a peripheral region 2B arranged outside the pixel region 2A to surround the pixel region 2A, in a two-dimensional plane.

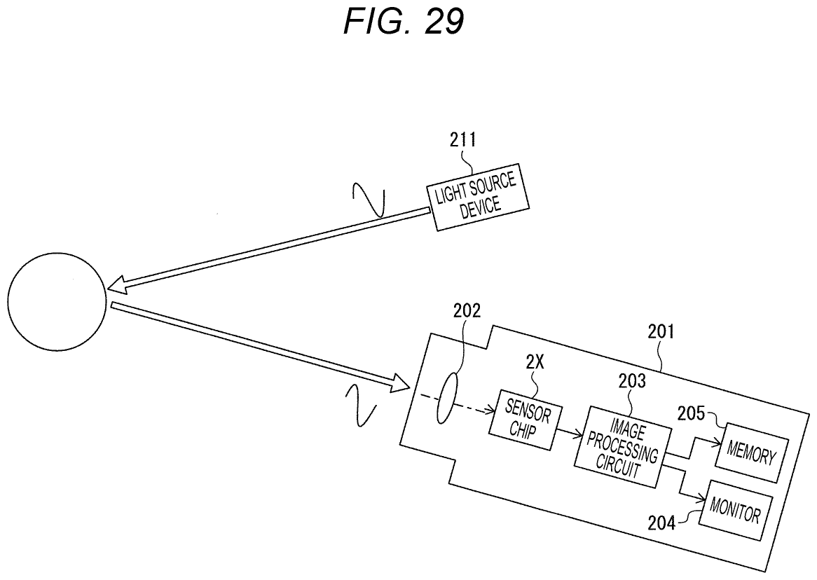

The pixel region 2A is a light receiving surface that receives light condensed by an optical system 202 in FIG. 29. As shown in FIG. 1, in the pixel region 2A, a plurality of pixels 3 is provided in an array along a row direction (X direction) and a column direction (Y direction) intersecting the row direction. Each pixel 3 includes a photoelectric conversion unit that performs photoelectric conversion. The thickness direction of the semiconductor chip 2 is parallel to the Z direction. The X direction and the Y direction are orthogonal to each other in the example of FIG. 1, but are not limited to the orthogonal state as long as they intersect each other. The Z direction is orthogonal to the X direction and the Y direction. Here, the Z direction is a thickness direction of the semiconductor chip 2, that is, a thickness direction of a first semiconductor substrate 20 to be described later, and is also a thickness direction of a second semiconductor substrate 40, a first semiconductor layer 21, a first wiring layer 31, a second semiconductor layer 41, and a second wiring layer 51 to be described later.

A plurality of electrode pads 14 is arranged in the peripheral region 2B. Each of the plurality of electrode pads 14 is arranged, for example, along four sides in a two-dimensional plane of the semiconductor chip 2. Each of the plurality of electrode pads 14 is an input/output terminal used when the semiconductor chip 2 is electrically connected to an external device (not shown).

### <Logic Circuit>

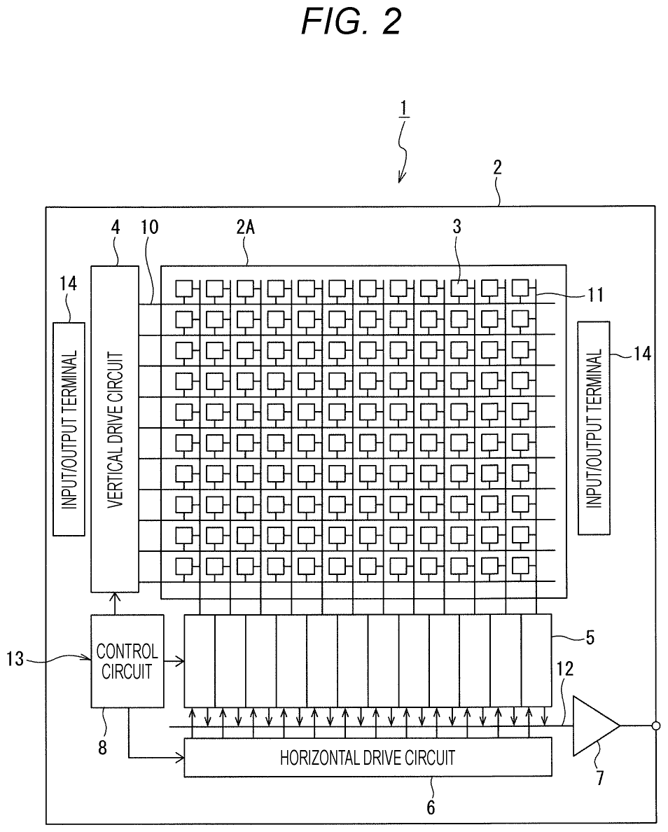

As shown in FIG. 2, the semiconductor chip 2 includes a logic circuit 13 including a vertical drive circuit 4, a column signal processing circuit 5, a horizontal drive circuit 6, an output circuit 7, a control circuit 8, and the like. The logic circuit 13 includes, for example, a complementary MOS (CMOS) circuit including an n-channel conductive type metal oxide semiconductor field effect transistor (MOSFET) and a p-channel conductive type MOSFET as field effect transistors.

The logic circuit 13 (specifically, the output circuit 7) outputs the output voltage for each pixel 3 to the outside. The vertical drive circuit 4 sequentially selects the plurality of pixels 3 row by row, for example. In addition, the vertical drive circuit 4 controls application of a bias voltage VB to an anode 24 of a light absorption unit 23 to be described later. The column signal processing circuit 5 performs, for example, correlated double sampling (CDS) processing on the pixel signal output from each pixel 3 in the row selected by the vertical drive circuit 4. The column signal processing circuit 5 extracts a signal level of a pixel signal by performing CDS processing, for example, and holds pixel data corresponding to the amount of light received by each pixel 3. The horizontal drive circuit 6 sequentially outputs the pixel data held in the column signal processing circuit 5 to a horizontal signal line 12, for example. The output circuit 7 performs signal processing on pixel signals sequentially supplied from each of the column signal processing circuits 5 through the horizontal signal line 12, and outputs the signals. The control circuit 8 controls driving of each block (the vertical drive circuit 4, the column signal processing circuit 5, the horizontal drive circuit 6, and the output circuit 7) in the logic circuit 13, for example.

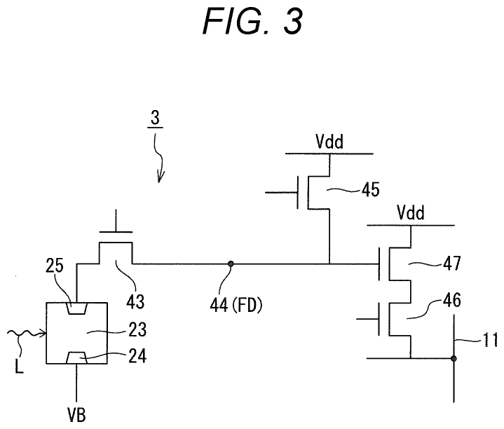

FIG. 3 is an equivalent circuit diagram showing a configuration example of the pixel 3. As shown in FIG. 3, a bias voltage VB which is a negative voltage is applied to the anode 24 of the light absorption unit 23, and a source of the transfer transistor 43 which is an active element is connected to a cathode 25 of the light absorption unit 23. A floating diffusion 44 in a floating state is connected to the drain of the transfer transistor 43. The floating diffusion 44 is connected to the source of the reset transistor 45 which is an active element and the gate of an amplification transistor 47 which is an active element. The source of the amplification transistor 47 is connected to the drain of a selection transistor 46 which is an active element, and the drain of the amplification transistor 47 is connected to a power source Vdd. The source of the selection transistor 46 is connected to a vertical signal line 11. The drain of the reset transistor 45 is connected to the power source Vdd.

### <Configuration of Semiconductor Chip>

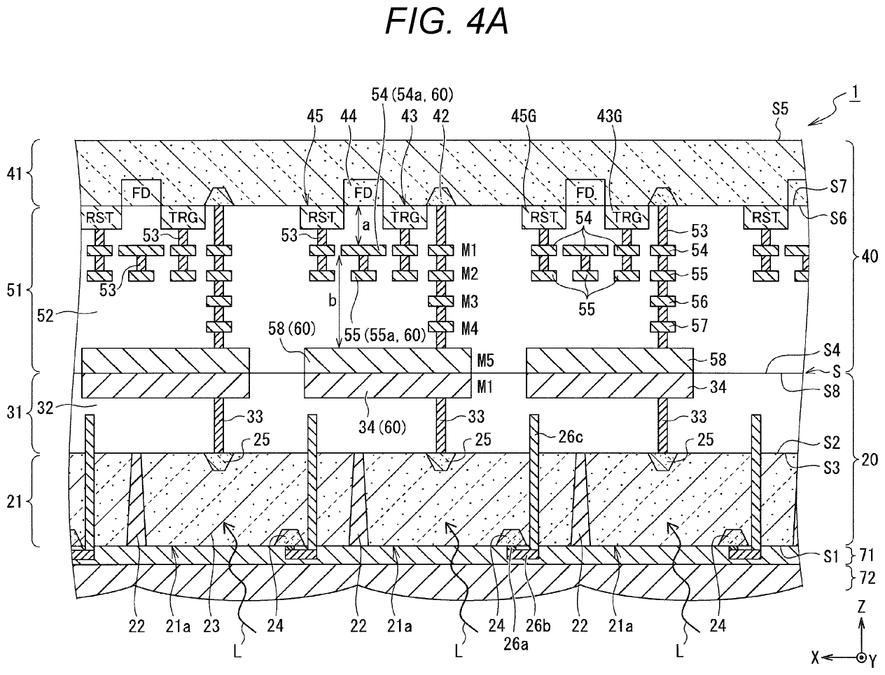

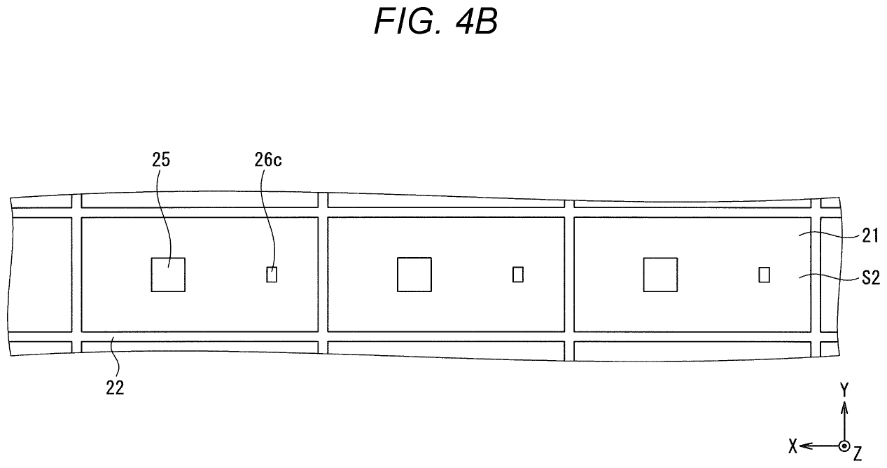

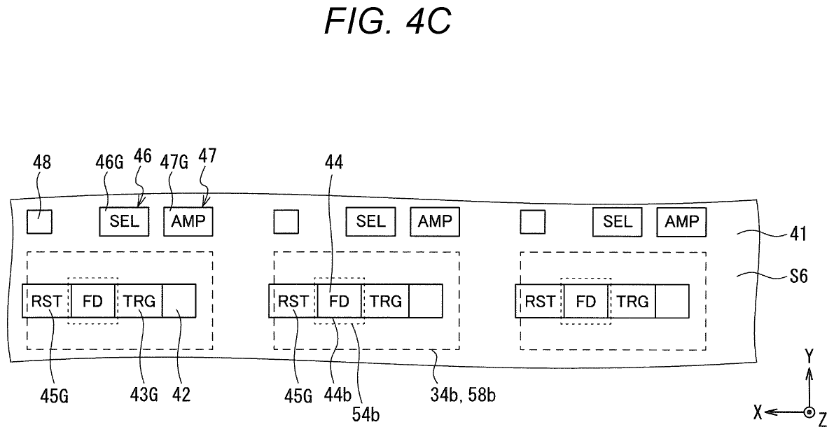

As shown in the longitudinal sectional view of FIG. 4A, the semiconductor chip 2 includes a first semiconductor substrate (photoelectric conversion substrate unit) 20 and a second semiconductor substrate (circuit substrate unit) 40 which are bonded to face each other. The first semiconductor substrate 20 includes the above-described pixel region 2A, and the second semiconductor substrate 40 includes at least a part of the logic circuit such as a readout circuit. Here, the first semiconductor substrate 20 and the second semiconductor substrate 40 are overlapped with and bonded to each other with a bonding surface S as a boundary. In addition, the semiconductor chip 2 includes a planarization film 71 and a microlens layer 72.

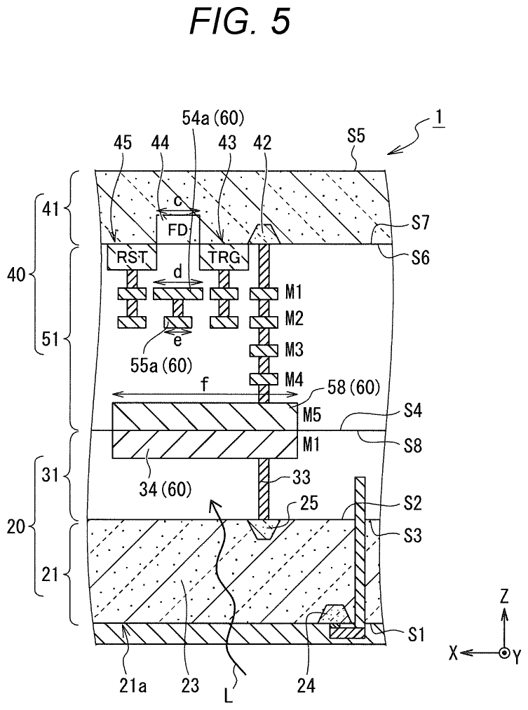

The first semiconductor substrate 20 includes a first semiconductor layer 21 which is an element side substrate and a first wiring layer 31. The first semiconductor layer 21 has a first surface S1 and a second surface S2 positioned on sides opposite to each other in the thickness direction (Z direction). Here, the first surface S1 may be referred to as a light incident surface or a back surface, and the second surface S2 may be referred to as a surface opposite to the light incident surface or an element forming surface. The first wiring layer 31 is provided on the second surface S2 of the first semiconductor layer 21, and the planarization film 71 and the microlens layer 72 are laminated in this order on the first surface S1. The first wiring layer 31 has a third surface S3 and a fourth surface S4 positioned on sides opposite to each other in the thickness direction. The third surface S3 is a surface on the first semiconductor layer 21 side and is in contact with the second surface S2. The fourth surface S4 is a surface opposite to the surface on the first semiconductor layer 21 side (third surface S3). Note that the microlens layer 72 will be omitted in FIG. 5 and subsequent drawings.

The second semiconductor substrate 40 includes a second semiconductor layer 41 which is a circuit side substrate and a second wiring layer 51. The second semiconductor layer 41 has a fifth surface S5 and a sixth surface S6 positioned on sides opposite to each other in the thickness direction. Here, the fifth surface S5 may be referred to as a back surface, and the sixth surface S6 may be referred to as one surface, an element forming surface, or a surface on the first semiconductor layer 21 side. The second wiring layer 51 is provided on the sixth surface S6 of the second semiconductor layer 41. The second wiring layer 51 has a seventh surface S7 and an eighth surface S8 positioned on sides opposite to each other in the thickness direction. The seventh surface S7 is a surface on the second semiconductor layer 41 side and is in contact with the sixth surface S6. The eighth surface S8 is a surface opposite to the surface on the second semiconductor layer 41 side (the seventh surface S7).

The second semiconductor substrate 40 is overlapped with and bonded to the first semiconductor substrate 20 such that the second wiring layer 51 is positioned between the first wiring layer 31 and the second semiconductor layer 41. Specifically, the first semiconductor substrate 20 and the second semiconductor substrate 40 are overlapped and bonded by being overlapped with and bonded to the fourth surface S4 of the first wiring layer 31 and the eighth surface S8 of the second wiring layer 51. The first semiconductor substrate 20 and the second semiconductor substrate 40 are also electrically connected.

### <Configuration of First Semiconductor Substrate>

As shown in FIGS. 4A and 4B, the first semiconductor substrate 20 includes a separation unit 22 that divides the first semiconductor layer 21 into a plurality of regions 21a. The separation unit 22 electrically and optically separates the adjacent regions 21a from each other. The separation unit 22 is, for example, a groove-shaped separation unit. The separation unit 22 has, for example, a single-layer structure including silicon oxide (SiO2) or a multilayer structure in which both sides of a metal film are sandwiched between insulating films.

### (Configuration of First Semiconductor Layer)

As shown in FIG. 4A, each of the regions 21a of the first semiconductor layer 21 includes the light absorption unit 23, a first contact region 24 which is a first conductive type (for example, p-type) diffusion region, and a second contact region 25 which is a second conductive type (for example, n-type) diffusion region that is different from the first conductive type. As the first semiconductor layer 21, for example, a semiconductor substrate including single crystal silicon is used.

When light L enters the light absorption unit 23 from the first surface S1 side (light incident surface side), the light absorption unit 23 performs photoelectric conversion. That is, the light absorption unit 23 functions as a photoelectric conversion unit that absorbs the light L and generates electrons (signal charge). The light absorption unit 23 is a first conductive type or second conductive type semiconductor region, but will be described as the first conductive type semiconductor region. The impurity concentration of the light absorption unit 23 is lower than the impurity concentration of the first contact region 24 and the second contact region 25.

A bias voltage VB is applied to the first semiconductor layer 21 in order to push out signal charge generated in the light absorption unit 23 from the first semiconductor substrate 20 side to the second semiconductor substrate 40 side. More specifically, the bias voltage VB is applied to the first contact region 24 which is the first conductive type diffusion region. The bias voltage VB is a negative voltage. When the bias voltage VB is applied to the first contact region 24, a potential gradient is formed in the light absorption unit 23, and signal charge is collected in the second conductive type second contact region 25 by the potential gradient. The first contact region 24 is provided in the first semiconductor layer 21 at a position closer to the first surface S1, and more specifically, a part thereof faces the first surface S1. In addition, the bias voltage VB is applied to the first contact region 24 via a via 26a, a wiring 26b, a through-silicon via (TSV) 26c penetrating the first semiconductor layer 21, a wiring (not shown), and the like, which are included in the first semiconductor substrate 20. The first contact region 24 reduces ohmic contact resistance with the via 26a and functions as an anode.

The second contact region 25, which is a diffusion region of the second conductive type, is provided in the first semiconductor layer 21 at a position closer to the second surface S2, and more specifically, a part thereof faces the second surface S2. The second contact region 25 reduces ohmic contact resistance with a via 33 to be described later and functions as a cathode. The second contact region 25 outputs signal charge from the first semiconductor layer 21.

### (Configuration of First Wiring Layer)

The first wiring layer 31 includes a first interlayer insulating film (insulating film) 32, a via 33, and a first metal film M1 on the element side. The first wiring layer 31 has a structure formed by laminating the first metal film M1 on the element side with the first interlayer insulating film 32 interposed therebetween.

The first metal film M1 on the element side includes a first connection pad 34. The first connection pad 34 is a connection pad provided in the first wiring layer 31. The first connection pad 34 faces the fourth surface S4 of the first wiring layer 31. In addition, the first connection pad 34 is provided at a position facing the floating diffusion 44 (hereinafter represented as FD 44) in the Z direction as shown in the longitudinal sections of FIGS. 4A and 5. The first connection pad 34 includes metal. The first connection pad 34 includes, for example, copper (Cu). Furthermore, the first connection pad 34 also functions as a light shielding layer 60 that shields light that has entered from the light incident surface side.

The via 33 electrically connects the first semiconductor layer 21 and the first connection pad 34. More specifically, the via 33 electrically connects the second contact region 25 and the first connection pad 34. The via 33 includes metal.

### <Configuration of Second Semiconductor Substrate>

### (Configuration of Second Semiconductor Layer)

As shown in FIGS. 4A and 4C, the second semiconductor layer 41 includes a third contact region 42, the transfer transistor 43, the FD 44, the reset transistor 45, the selection transistor 46, the amplification transistor 47, and a well contact 48. As the second semiconductor layer 41, for example, a semiconductor substrate including single crystal silicon is used.

The third contact region 42 is a diffusion region of the same conductive type as the second contact region 25, that is, the second conductive type. The third contact region 42 is electrically connected to the second contact region 25, and receives signal charge from the second contact region 25 when the bias voltage VB is applied to the first contact region 24. The third contact region 42 reduces ohmic contact resistance with a via 53 to be described later.

The transfer transistor 43 is, for example, an n-channel MOSFET. The transfer transistor 43 is provided to form a channel between the third contact region 42 and the FD 44, and includes a gate insulating film (not shown) and a transfer gate electrode 43G sequentially laminated on the sixth surface S6.

The transfer transistor 43 transfers the signal charge obtained by photoelectric conversion of the light absorption unit 23 to the FD 44. More specifically, the transfer transistor 43 transfers the signal charge from the third contact region 42 that functions as the source region to the FD 44 that functions as the drain region according to the voltage between the gate and the source. The transfer transistor 43 is conventionally provided in the first semiconductor layer 21, but is repositioned to the second semiconductor layer 41 in the present technology.

The FD 44 is a charge accumulation region that temporarily accumulates the signal charge transferred from the third contact region 42. That is, the FD 44 functions as a charge holding unit. The FD 44 is a floating diffusion region of the same conductive type as the second contact region 25, that is, the second conductive type. The FD 44 is provided in the second semiconductor layer 41. Specifically, the FD 44 is embedded in the second semiconductor layer 41. The FD 44 is conventionally provided in the first semiconductor layer 21, but is repositioned to the second semiconductor layer 41 in the present technology.

The reset transistor 45 is, for example, an n-channel MOSFET. The reset transistor 45 includes a gate insulating film (not shown) and a reset gate electrode (RST) 45G sequentially laminated on the sixth surface S6. The reset transistor 45 resets the potential of the FD 44 to a predetermined potential according to the voltage between the gate and the source.

The selection transistor 46 is, for example, an n-channel MOSFET. The selection transistor 46 includes a gate insulating film (not shown) and a selection gate electrode (SEL) 46G sequentially laminated on the sixth surface S6. The selection transistor 46 controls the output timing of the pixel signal from the readout circuit according to the voltage between the gate and the source.

The amplification transistor 47 is, for example, an re-channel MOSFET. The amplification transistor 47 includes a gate insulating film (not shown) and an amplification gate electrode (AMP) 47G sequentially laminated on the sixth surface S6. When the selection transistor 46 is in an on state, the amplification transistor 47 amplifies the potential of the FD 44.

The well contact 48 is fixed at a predetermined potential.

### (Configuration of Second Wiring Layer)

As shown in FIG. 4A, the second wiring layer 51 includes a second interlayer insulating film (insulating film) 52, the first metal film M1 to a fifth metal film M5 on the circuit side, and the via 53. The second wiring layer 51 has a structure in which the first metal film M1 to the fifth metal film M5 on the circuit side are laminated in this order from the seventh surface S7 side via the second interlayer insulating film 52.

The first metal film M1 on the circuit side includes a metal layer 54, the second metal film M2 includes a metal layer 55, the third metal film M3 includes a metal layer 56, the fourth metal film M4 includes a metal layer 57, and the fifth metal film M5 includes a second connection pad 58. For example, the first metal film M1 on the circuit side includes a plurality of metal layers 54. The plurality of metal layers 54 is formed by the same process. The same applies to the first metal film M1 and the second metal film M2 to the fifth metal film M5 on the element side.

The metal layer 54 to the metal layer 57 include metal. The metal layers 54 to 57 include, for example, copper (Cu) or aluminum (Al). The second connection pad 58 includes metal. The second connection pad 58 includes, for example, copper (Cu).

Among the plurality of metal layers 54, the metal layer 54 provided at a position facing the FD 44 in the Z direction is referred to as a metal layer 54a in order to be distinguished from the other metal layers 54. Furthermore, among the plurality of metal layers 55, the metal layer 55 provided at a position facing the FD 44 in the Z direction is referred to as a metal layer 55a in order to be distinguished from the other metal layers 55. Each of the metal layer 54a, the metal layer 55a, and the second connection pad 58 functions as the light shielding layer 60 that shields light that has entered from the light incident surface side.

The via 53 electrically connects metal films of different layers. The via 53 electrically connects any two of the first metal film M1 to the fifth metal film M5 on the circuit side. For example, the via 53 electrically connects the metal layer 54 and the metal layer 55. Further, the via 53 electrically connects the metal film and the gate electrode. For example, the via 53 electrically connects the metal layer 54 and the transfer gate electrode 43G. Moreover, the via 53 electrically connects the second semiconductor layer 41, more specifically, the third contact region 42 and the first metal film M1. For example, the via 53 electrically connects the third contact region 42 and the metal layer 54. The via 53 includes metal.

The second connection pad 58 is a connection pad provided in the second wiring layer 51. The second connection pad 58 faces the eighth surface S8 of the second wiring layer 51. The second connection pad 58 is provided at a position facing the FD 44 in the Z direction. The second connection pad 58 is electrically connected to the second semiconductor layer 41, more specifically, the third contact region 42 via at least one of the via 53 or the wiring. For example, as shown in the drawing, the second connection pad 58 is electrically connected to the third contact region 42 from the metal layer 54 via the metal layer 57 and the via 53. The second connection pad 58 is bonded to first connection pad 34. As a result, the first semiconductor layer 21 of the first semiconductor substrate 20 and the second semiconductor layer 41 of the second semiconductor substrate 40 are electrically connected. More specifically, the second contact region 25 and the third contact region 42 are electrically connected.

### <Configuration of Light Shielding Layer>

Hereinafter, the light shielding layer 60 will be described with reference to FIGS. 4A, 4C, and 5. The light shielding layer 60 has a role of shielding at least a part of the light that has entered from the light incident surface before the light reaches the FD 44. Therefore, the light shielding layer 60 is provided closer to the light incident surface than the sixth surface S6 of the second semiconductor layer 41 provided with the FD 44 in the thickness direction of the solid-state imaging device 1. More specifically, the light shielding layer 60 is provided between the first semiconductor layer 21 and the second semiconductor layer 41, that is, in the first wiring layer 31 and the second wiring layer 51. Furthermore, the light shielding layer 60 is provided at a position facing the FD 44 in the Z direction. That is, the position of the light shielding layer 60 in the horizontal direction is a position facing the FD 44. Here, the horizontal direction is a direction perpendicular to the Z direction.

A plurality of light shielding layers 60 is provided. The light shielding layer 60 includes the first metal film M1, the second metal film M2, and the fifth metal film M5 on the circuit side and the first metal film M1 on the element side, which are provided in the first wiring layer 31 and the second wiring layer 51. That is, the light shielding layer 60 includes the second connection pad 58 including the metal layer 54a including the first metal film M1 on the circuit side, the metal layer 55a including the second metal film M2, and the fifth metal film M5, and the first connection pad 34 including the first metal film M1 on the element side.

FIG. 4C is a diagram showing a relative relationship between the respective components when the second semiconductor layer 41 is viewed in cross section on the surface of the sixth surface S6. In FIG. 4C, a contour 54b of the metal layer 54a, a contour 34b of the first connection pad 34, and a contour 58b of the second connection pad 58 are projected. In plan view, the metal layer 54a, the first connection pad 34, and the second connection pad 58 overlap the entire FD 44. In other words, in plan view, the contour 54b and the contours 34b and 58b are outside the contour 44b of the FD 44. Further, the contours 34b and 58b are outside the contour 54b. When the light shielding layer 60 overlaps the entire FD 44, the effect of covering the FD 44 increases. Therefore, the light L traveling along the thickness direction of the second wiring layer 51 hardly enters the FD 44. Furthermore, the larger the area of the light shielding layer 60, the greater the effect of covering the FD 44. Therefore, the light L traveling along the oblique direction hardly enters the FD 44. The oblique direction is a direction intersecting the Z direction.

The light shielding layer 60 is preferably a metal layer closer to the second semiconductor layer 41, more specifically, the FD 44 in the thickness direction of the second wiring layer 51. The metal layer 54a is a metal layer closest to the second semiconductor layer 41 in the thickness direction of the second wiring layer 51 among the plurality of light shielding layers 60 provided at positions facing the FD 44 in the Z direction in the second wiring layer 51.

Furthermore, the light shielding layer 60 preferably includes a metal film closer to the second semiconductor layer 41, more specifically, the FD 44 in the thickness direction of the second wiring layer 51. The metal layer 54a includes the first metal film M1 on the circuit side which is a metal film closest to the second semiconductor layer 41, more specifically, the FD 44 in the thickness direction of the second wiring layer 51 among the plurality of layers of the first metal film M1 to the fifth metal film M5 on the circuit side provided in the second wiring layer 51.

The light shielding effect of the light shielding layer 60 increases as the distance between the light shielding layer 60 and the second semiconductor layer 41 in the thickness direction of the second wiring layer 51, more specifically, the distance between the light shielding layer 60 and the FD 44 decreases. Therefore, from the viewpoint of the distance distribution in the thickness direction of the second wiring layer 51, the metal layer 54a is more advantageous in light shielding than the other light shielding layers 60.

A distance in the thickness direction of the second wiring layer 51 between the metal layer 54a and the FD 44 is represented as a distance a. As the distance a is smaller, it is more advantageous for light shielding. That is, as the distance a decreases, the metal layer 54a comes closer to the FD 44, and the effect that the metal layer 54a covers the FD 44 increases. Then, the light L traveling along the oblique direction hardly enters the FD 44.

In addition, a distance in the thickness direction of the second wiring layer 51 between the metal layer 54a and the second connection pad 58 is represented as a distance b. Comparing the distance a with the distance b, the distance a is equal to or less than the distance b (a b). Furthermore, the distance a may be significantly smaller than the distance b (a<<b).

As shown in FIGS. 4A and 5, the second connection pad 58 is a light shielding layer closest to the light incident surface among the light shielding layers 60 provided in the second wiring layer 51, and is a light shielding layer farthest from the FD 44. In a case where a plurality of metal layers is present between the second connection pad 58 and the metal layer 54a, it may be difficult to reduce the distance b. However, increasing the width f and the area of the second connection pad 58 is less restricted than increasing the area of the metal layer 54a. Therefore, the area of the second connection pad 58 can be made significantly larger than the area of the metal layer 54a. The second connection pad 58 having the large width f and area is effective as the light shielding layer 60 even when the second connection pad 58 is far from the FD 44.

The first connection pad 34 is a light shielding layer closest to the light incident surface among the light shielding layers 60 provided in the first wiring layer 31 and the second wiring layer 51, and is a light shielding layer farthest from the FD 44. The first connection pad 34 also has the same configuration and effect as those of the second connection pad 58.

As shown in FIG. 5, the width d of the metal layer 54a in the X direction is larger than the width c of the FD 44 in the X direction. On the other hand, the width e of the metal layer 55a in the X direction is smaller than the width c of the FD 44 in the X direction. The metal layer 54a does not overlap the entire FD 44, and overlaps only a part of the FD 44. As described above, even in a case where the light shielding layer 60 overlaps only a part of the FD 44, at least a part of the light L can be shielded. Then, the greater the overlap between the light shielding layer 60 and the FD 44, the greater the light shielding effect of the light shielding layer 60.

In addition, although the metal layer 54a, the metal layer 55a, the first connection pad 34, and the second connection pad 58 function as the light shielding layer 60 alone, the light shielding effect is further increased by combining the plurality of light shielding layers 60. This is because, when the light L travels from the light incident surface side to the second semiconductor layer 41 side, the light L is sequentially blocked by the light shielding layers 60 provided at different positions in the thickness direction of the first wiring layer 31 and the second wiring layer 51.

In particular, the combination of the metal layer 54a closest to the second semiconductor layer 41 in the thickness direction of the second wiring layer 51 among the plurality of metal layers provided in the second wiring layer 51 at positions facing the FD 44 in the Z direction, and at least one of a connection pad out of the first connection pad 34 provided in the first wiring layer 31 and the second connection pad 58 provided in the second wiring layer 51 and bonded to the first connection pad 34 is useful. This is because the combination of the first connection pad 34 or the second connection pad 58 having a large area and the metal layer 54a closest to the FD 44 can take advantage of each other's strengths.

### <Reset Operation of FD and Light Absorption Unit>

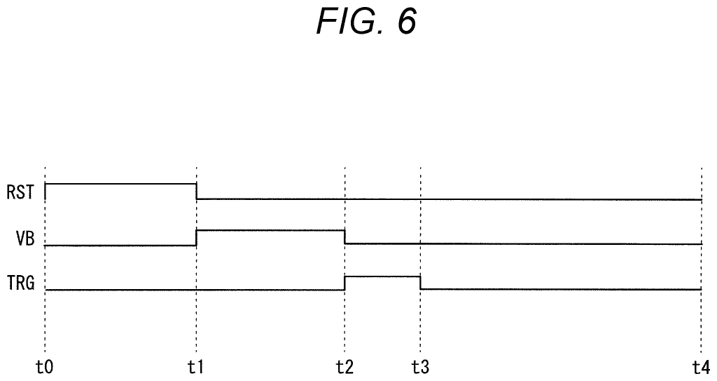

Next, a reset operation of the FD 44 and the light absorption unit 23 will be described with reference to the timing chart of FIG. 6. By resetting the FD 44 and the light absorption unit 23, parasitic light sensitivity (PLS) can be further suppressed.

A period from time t0 to time t1 is a first reset period in which the FD 44 and the light absorption unit 23 are reset. A period from time t1 to time t2 is an accumulation period in which signal charge generated by photoelectric conversion is accumulated. A period from time t2 to time t3 is a transfer period in which the signal charge accumulated by the transfer transistor 43 is transferred to the FD 44. A period from time t3 to time t4 is a second reset period in which the light absorption unit 23 is reset.

Furthermore, FIG. 6 shows on/off timing of the reset transistor 45 (RST), timing of application of the bias voltage VB to the light absorption unit 23, and on/off timing of the transfer transistor 43 (TRG). The reset transistor 45 is in an on state only during the first reset period. The bias voltage VB is applied to the light absorption unit 23 only during the accumulation period. Then, the transfer transistor 43 is in an on state only during the transfer period.

In the first reset period, the reset transistor 45 is turned on, and the signal charge remaining in the FD 44 is discharged. In addition, the application of the bias voltage VB to the light absorption unit 23 is stopped. When the application of the bias voltage VB to the light absorption unit 23 is stopped, the signal charge generated by the photoelectric conversion is recombined in the light absorption unit 23 and disappears. In this manner, PLS can be suppressed by removing the signal charge remaining in the FD 44 and the light absorption unit 23.

During the next accumulation period, signal charge is generated by photoelectric conversion of the light absorption unit 23. In addition, during this accumulation period, the bias voltage VB is applied to the light absorption unit 23 in order to push out signal charge from the first semiconductor substrate 20 side to the second semiconductor substrate 40 side.

During the transfer period, the signal charge pushed out to the second semiconductor substrate 40 side is transferred to the FD 44 by the transfer transistor 43. In addition, during the transfer period, the application of the bias voltage VB to the light absorption unit 23 is stopped, and the signal charge in the light absorption unit 23 is recombined and disappears.

During the last second reset period, a state where the application of the bias voltage VB to the light absorption unit 23 is stopped continues, and the signal charge in the light absorption unit 23 is recombined and disappears.

### <Effect>

In the solid-state imaging device 1 according to the first embodiment, since the FD 44 conventionally provided in the first semiconductor layer 21 is repositioned to the second semiconductor layer 41, the metal layers provided in the first wiring layer 31 and the second wiring layer 51 can be used as the light shielding layer 60 that suppresses incidence of the light L on the FD 44.

Furthermore, the light shielding layer 60 is provided at a position facing the FD 44 in the Z direction. Therefore, since at least a part of the light L traveling toward the FD 44 is blocked by the light shielding layer 60, it is possible to suppress photoelectric conversion from being performed in the FD 44. As a result, PLS can be suppressed.

Furthermore, in the solid-state imaging device 1 according to the first embodiment, since the light shielding layer 60 overlaps the entire FD 44 in plan view, the effect of covering the FD 44 is increased. The light L traveling along the thickness direction of the solid-state imaging device 1 can be shielded.

Furthermore, the metal layer 54a is a light shielding layer closest to the second semiconductor layer 41 in the thickness direction of the second wiring layer 51 among the plurality of light shielding layers 60 provided at positions facing the FD 44 in the Z direction in the second wiring layer 51. In addition, the metal layer 54a includes a metal film closer to the second semiconductor layer 41 in the thickness direction of the second wiring layer 51. As a result, the distance a in the thickness direction of the second wiring layer 51 between the metal layer 54a which is the light shielding layer 60 and the FD 44 can be reduced, and thus the light L traveling along the oblique direction hardly enters the FD 44.

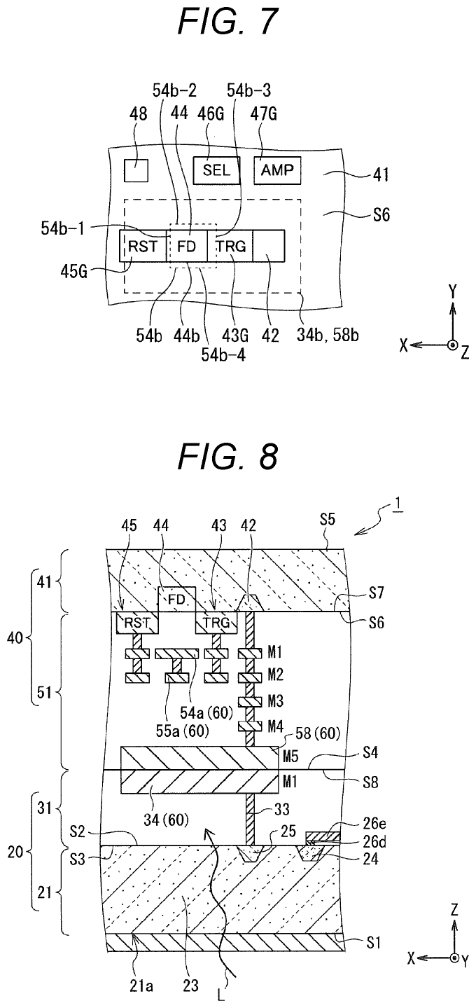

In the present first embodiment, the metal layer 54a overlaps the entire FD 44 in plan view, but may overlap only a part of the FD 44 similar to the metal layer 55a. FIG. 7 is an example of such a configuration. Among the four sides 54b-1, 54b-2, 54b-3, and 54b-4 constituting the contour 54b of the metal layer 54a, some or all of the sides may be positioned inside the contour 44b of the FD 44. Even with such a configuration, the metal layer 54a can block at least a part of the light L, and thus, has a light shielding effect. Then, the greater the overlap between the light metal layer 54a and the FD 44, the greater the light shielding effect of the metal layer 54a.

In addition, in the present first embodiment, the light shielding layer 60 such as the metal layer 54a and the metal layer 55a may be a metal layer dedicated to light shielding or may have a function as an electrical conduction path or a terminal. In the present first embodiment, the first connection pad 34 and the second connection pad 58 electrically connect the first semiconductor substrate 20 and the second semiconductor substrate 40, but may be a metal layer dedicated to light shielding.

Note that, in the present first embodiment, the solid-state imaging device 1 is a distance image sensor that performs distance measurement by the ToF method, but the solid-state imaging device 1 may be a solid-state imaging device that captures a two-dimensional image having no distance information. In that case, the solid-state imaging device 1 may include a color filter or the like.

Furthermore, the present technology can be applied to both a global shutter that simultaneously shuts off the shutter in all rows and a rolling shutter that shuts off the shutter in each row. Since the global shutter has a slower reading speed than the rolling shutter, the effect of applying the present technology is greater from the viewpoint of PLS suppression.

In the present first embodiment, the bias voltage VB is a negative voltage, but may be fixed to the ground (reference potential).

In addition, the number of layers of the metal film on the element side and the number of layers of the metal film on the circuit side are not limited to the number of layers described in the first embodiment.

### Modification Example 1 of First Embodiment

Modification Example 1 of the first embodiment of the present technology shown in FIG. 8 will be described below. The solid-state imaging device 1 according to Modification Example 1 of the present first embodiment is different from the solid-state imaging device 1 according to the first embodiment described above in the position of the first contact region, and the other configurations of the solid-state imaging device 1 are basically similar to those of the solid-state imaging device 1 according to the first embodiment described above. Note that the components already described will be denoted by the same reference numerals, and the description thereof will be omitted.

The first contact region 24 is provided in the first semiconductor layer 21 at a position closer to the second surface S2, and more specifically, a part thereof faces the second surface S2. In addition, the bias voltage VB is applied to the first contact region 24 via the via 26d, the wiring 26e, and the like of the first semiconductor substrate 20.

### <Effect>

Even in the solid-state imaging device 1 according to Modification Example 1 of the first embodiment, the same effects as those of the solid-state imaging device 1 according to the first embodiment described above can be obtained.

### Modification Example 2 of First Embodiment

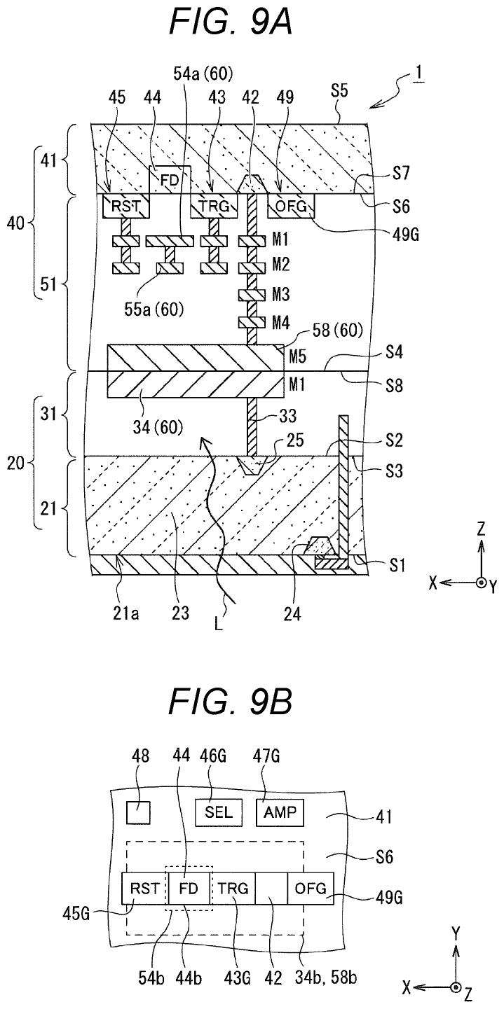

Modification Example 2 of the first embodiment of the present technology shown in FIGS. 9A and 9B will be described below. The solid-state imaging device 1 according to Modification Example 2 of the present first embodiment is different from the solid-state imaging device 1 according to the first embodiment described above in that a discharge transistor 49 is provided, and the other configurations of the solid-state imaging device 1 are basically similar to those of the solid-state imaging device 1 according to the first embodiment described above. Note that the components already described will be denoted by the same reference numerals, and the description thereof will be omitted.

The second semiconductor layer 41 includes the third contact region 42, the transfer transistor 43, the FD 44, the reset transistor 45, the selection transistor 46, the amplification transistor 47, the well contact 48, and the discharge transistor 49.

The discharge transistor 49 is, for example, an n-channel MOSFET. The discharge transistor 49 that includes a gate insulating film (not shown) and a discharge gate electrode (OFG) 49G which are sequentially laminated on the sixth surface S6 has the third contact region 42 as a source, and discharges the signal charge from the third contact region 42 according to the voltage between the gate and the source.

### <Reset Operation of FD and Light Absorption Unit>

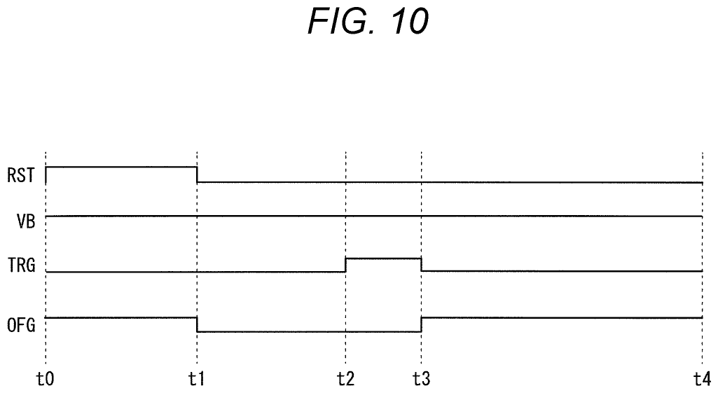

Next, a reset operation of the FD 44 and the light absorption unit 23 will be described with reference to the timing chart of FIG. 10. Note that the same components as those of FIG. 6 of the first embodiment will be denoted by the same reference numerals, and the description thereof will be omitted.

FIG. 10 further shows on/off timing of the discharge transistor 49 (OFG). Then, the discharge transistor 49 is in an on state during the first reset period and the second reset period, and in an off state during the accumulation period and the transfer period. Furthermore, unlike the case of the first embodiment described above, the bias voltage VB is applied to the light absorption unit 23 during all the periods of the first reset period, the accumulation period, the transfer period, and the second reset period.

When the discharge transistor 49 is turned on during the first reset period and the second reset period, signal charge is discharged from the third contact region 42 during the same period. As a result, PLS can be suppressed even when the bias voltage VB is constantly applied to the light absorption unit 23.

### <Effect>

Even in the solid-state imaging device 1 according to Modification Example 2 of the first embodiment, the same effects as those of the solid-state imaging device 1 according to the first embodiment described above can be obtained.

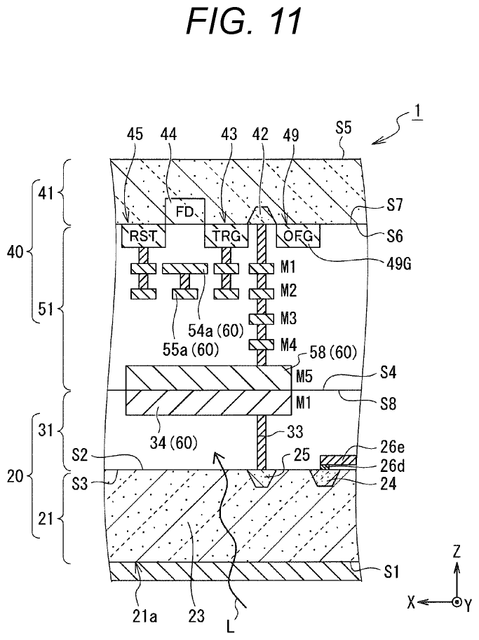

Note that, as shown in FIG. 11, the solid-state imaging device 1 according to Modification Example 1 of the first embodiment may include the discharge transistor 49.

### Modification Example 3 of First Embodiment

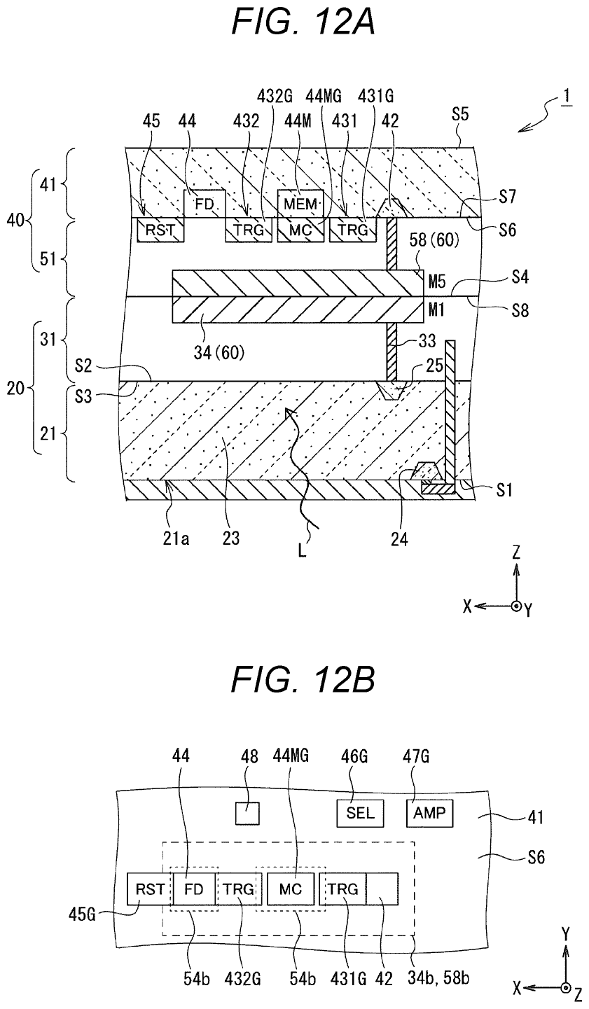

Modification Example 3 of the first embodiment of the present technology shown in FIGS. 12A and 12B will be described below. The solid-state imaging device 1 according to Modification Example 3 of the present first embodiment is obtained by applying the technology of the first embodiment described above to a memory-holding type global shutter, and other configurations of the solid-state imaging device 1 are basically similar to those of the solid-state imaging device 1 of the first embodiment described above. Note that the components already described will be denoted by the same reference numerals, and the description thereof will be omitted.

The second semiconductor layer 41 includes a first transfer transistor 431 having a first transfer gate electrode 431G and a second transfer transistor 432 having a second transfer gate electrode 432G instead of the transfer transistor 43 of the first embodiment. The second semiconductor layer 41 further includes a memory 44M and an MC gate 44MG. Other configurations are equivalent to those of the first embodiment.

The first transfer transistor 431 transfers the signal charge from the third contact region 42 to the memory 44M. The memory 44M is a charge accumulation region that temporarily accumulates the signal charge transferred from the third contact region 42. That is, the memory 44M functions as a charge holding unit. The memory 44M is a floating diffusion region of the same conductive type as the second contact region 25, that is, the second conductive type. The memory 44M is provided in the second semiconductor layer 41. Specifically, the memory 44M is embedded in the second semiconductor layer 41. The memory 44M is conventionally provided in the first semiconductor layer 21, but is repositioned to the second semiconductor layer 41 in the present technology. The second transfer transistor 432 transfers the signal charge accumulated in the memory 44M to the FD 44. The FD 44 is a charge accumulation region that temporarily accumulates the signal charge transferred from the memory 44M. That is, the FD 44 functions as a charge holding unit.

### <Configuration of Light Shielding Layer>

The light shielding layer 60 shields at least a part of the light that has entered from the light incident surface before the light reaches the FD 44 and the memory 44M. In FIG. 12A, the metal layer 54 to the metal layer 57 will be omitted in the drawing, but at least one of the metal layers functions as the light shielding layer 60 of the memory 44M.

### <Effect>

Even in the solid-state imaging device 1 according to Modification Example 3 of the first embodiment, the same effects as those of the solid-state imaging device 1 according to the first embodiment described above can be obtained.

### Second Embodiment

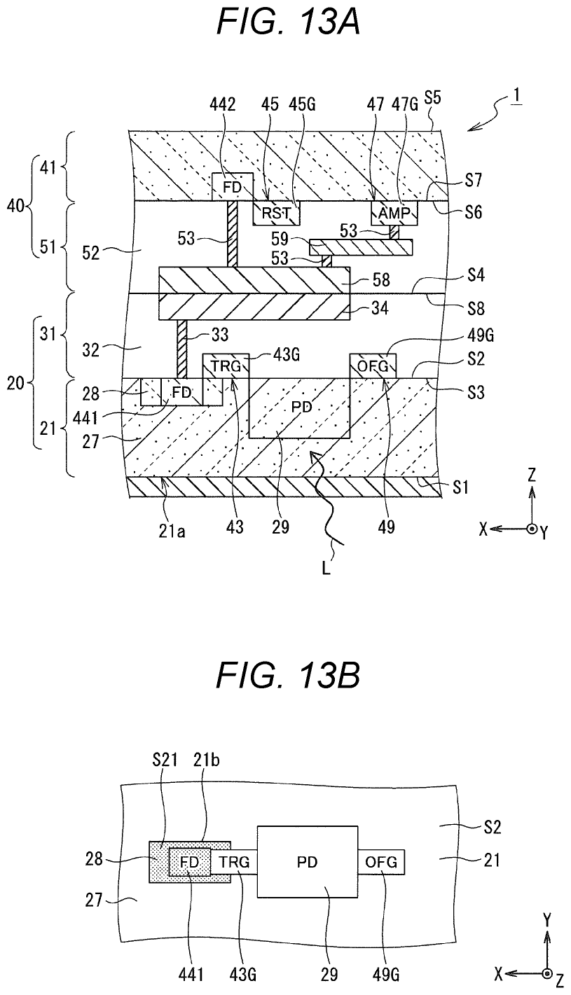

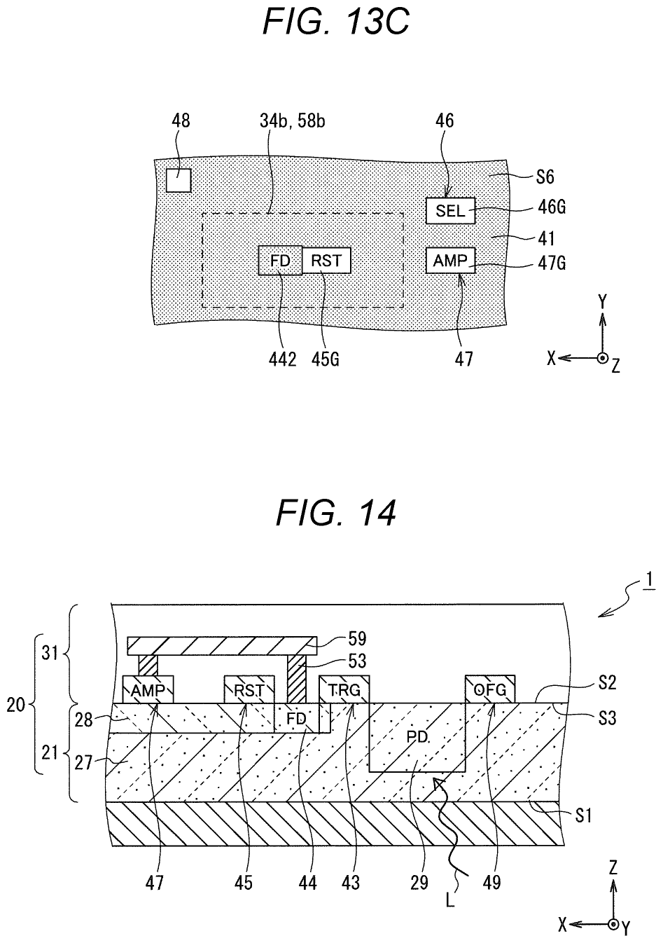

The second embodiment of the present technology shown in FIGS. 13A to 13C will be described below. The solid-state imaging device 1 according to the present second embodiment is different from the solid-state imaging device 1 according to the first embodiment described above in that, in the first semiconductor layer 21, the photoelectric conversion unit is provided in the first region including the first semiconductor material, and the floating diffusion is provided in the second region including the second semiconductor material having a lower quantum efficiency than that of the first semiconductor material, and other configurations of the solid-state imaging device 1 are basically similar to those of the solid-state imaging device 1 according to the first embodiment described above. Note that the components already described will be denoted by the same reference numerals, and the description thereof will be omitted.

### <Configuration of First Semiconductor Substrate>

### (Configuration of First Semiconductor Layer)

As shown in FIG. 29, distance image equipment 201 acquires a distance image according to a distance to a subject by receiving light (modulated light or pulsed light) projected from a light source device 211 toward the subject and reflected on a surface of the subject. At that time, the light source device 211 emits light of a specific wavelength or a certain wavelength band, and the solid-state imaging device receives the light. In the second embodiment of the present technology, the first semiconductor material and the second semiconductor material having different sensitivities to light emitted from the light source device 211 are used.

The first semiconductor layer 21 includes a first region 27 including a first semiconductor material and a second region 28 including a second semiconductor material having a quantum efficiency lower than that of the first semiconductor material. Here, the quantum efficiency indicates a probability (efficiency) that photons are converted into electrons. That is, for light of a specific wavelength, the quantum efficiency of the second semiconductor material is lower than the quantum efficiency of the first semiconductor material. The combination of the first semiconductor material and the second semiconductor material is a combination of two different materials of silicon (Si), germanium (Ge), silicon germanium (SiGe), gallium arsenide (GaAs), indium gallium arsenide (InGaAs), and copper indium gallium selenium (CIGS), and the second semiconductor material is a material having lower quantum efficiency out of the two materials. In addition, silicon has the lowest quantum efficiency among the above-described materials. Therefore, the second semiconductor material may be silicon, and the first semiconductor material combined with the second semiconductor material may be any one of germanium, silicon germanium, gallium arsenide, indium gallium arsenide, and copper indium gallium selenium.

In the second embodiment of the present technology, a description will be given on the assumption that the light source device 211 emits IR light (infrared light) and the solid-state imaging device receives IR light. Furthermore, in the second embodiment of the present technology, a combination of germanium (first semiconductor material) and silicon (second semiconductor material) will be described as an example.

Each of the regions 21a of the first semiconductor layer 21 includes a first region 27 including germanium and a second region 28 including silicon. The first region 27 and the second region 28 are three-dimensional regions. The second region 28 is formed, for example, by cutting a part of a wafer including germanium and embedding silicon in the cut part. Furthermore, as another example, the second region 28 may be formed by growing silicon at a scraped part of the germanium wafer, or the like. Silicon is lower in quantum efficiency and sensitivity to IR light than germanium.

As shown in FIG. 13A, the second region 28 is provided in the first semiconductor layer 21 at a position closer to the second surface S2 in the thickness direction of the first semiconductor layer 21. In addition, the second region 28 faces the second surface S2 which is a surface opposite to the light incident surface among surfaces of the first semiconductor layer 21. More specifically, as shown in FIG. 13B, the second region 28 faces the second surface S2 only in the first range S21 that is a part of the second surface S2. The first range S21 is a region surrounded by a contour line 21b.

The first region 27 is present around a surface other than the surface facing the first range S21 of the second region 28. In particular, only the first region 27 is provided as a region at a part of the first semiconductor layer 21 closer to the light incident surface than the second region 28 in the thickness direction. In addition, the first region 27 faces the entire partial surface of the second surface S2 other than the first range S21.

Each of the regions 21a of the first semiconductor layer 21 includes a photodiode 29, the transfer transistor 43, a floating diffusion 441 (hereinafter referred to as an FD 441), and the discharge transistor 49.

The photodiode 29 is provided in the first region 27 including germanium. That is, a material having sensitivity in a long wavelength band as compared with silicon is used for the photodiode 29. When the light L enters the photodiode 29 from the first surface S1 side (light incident surface side), the photodiode 29 performs photoelectric conversion. That is, the photodiode 29 functions as a photoelectric conversion unit that absorbs the light L and generates electrons (signal charge).

The transfer transistor 43 is, for example, an n-channel MOSFET. The transfer transistor 43 is provided to form a channel between the photodiode 29 and the FD 441, and includes the gate insulating film (not shown) and the transfer gate electrode 43G sequentially laminated on the second surface S2.

The transfer transistor 43 transfers the signal charge from the photodiode 29 that functions as the source region to the FD 441 that functions as the drain region according to the voltage between the gate and the source.

The FD 441 is provided in the second region 28 including silicon. The FD 441 is a charge accumulation region that temporarily accumulates the signal charge transferred from the photodiode 29. That is, the FD 441 functions as a charge holding unit. The FD 441 is, for example, a floating diffusion region of the second conductive type.

The discharge transistor 49 is, for example, an n-channel MOSFET. The discharge transistor 49 that includes a gate insulating film (not shown) and the discharge gate electrode (OFG) 49G which are sequentially laminated on the second surface S2 has the photodiode 29 as a source, and discharges the signal charge from the photodiode 29 according to the voltage between the gate and the source.

### (Configuration of First Wiring Layer)

The first wiring layer 31 includes the first interlayer insulating film (insulating film) 32, the via 33, and the first connection pad 34. The via 33 electrically connects the FD 441 and the first connection pad 34.

### <Configuration of Second Semiconductor Substrate>

### (Configuration of Second Semiconductor Layer)

As shown in FIGS. 13A and 13C, the second semiconductor layer 41 includes a floating diffusion 442 (hereinafter represented as an FD 442), the reset transistor 45, the selection transistor 46, the amplification transistor 47, and the well contact 48. As the second semiconductor layer 41, for example, a semiconductor substrate including single crystal silicon is used.

The FD 442 is a charge accumulation region that is electrically connected to the FD 441 and temporarily accumulates signal charge generated by photoelectric conversion. That is, the FD 442 functions as a charge holding unit. The FD 442 is, for example, a floating diffusion region of the second conductive type.

The reset transistor 45 resets the potential of the FD 442 to a predetermined potential according to the voltage between the gate and the source.

### (Configuration of Second Wiring Layer)

The second wiring layer 51 includes the second interlayer insulating film (insulating film) 52, the via 53, a metal layer 59 which is a wiring, and the second connection pad 58.

The FD 442 and the second connection pad 58 are electrically connected via the via 53. The FD 442 and the second connection pad 58 may be electrically connected via a metal layer (not shown) in addition to the via 53.

The second connection pad 58 is bonded to the first connection pad 34. As a result, the FD 441 and the FD 442 are electrically connected. In addition, the amplification gate electrode 47G and the second connection pad 58 are electrically connected via the via 53 and the metal layer 59.

### <Effect>

The IR light is light having a wavelength of approximately 780 nm to 1 mm. Germanium is sensitive to light mainly in a long wavelength band of 1000 nm to 1500 nm. That is, germanium performs photoelectric conversion mainly on light of 1000 nm to 1500 nm. In contrast, silicon exhibits sensitivity mainly to light of 400 nm to 800 nm. That is, silicon performs photoelectric conversion mainly on light of 400 nm to 800 nm. That is, the sensitivity of silicon to IR light is lower than the sensitivity of germanium. In other words, for IR light, the quantum efficiency of silicon is lower than the quantum efficiency of germanium.

In a case where germanium and silicon are irradiated with IR light of the same intensity, the signal charge generated by photoelectric conversion with silicon is sufficiently smaller than the amount of signal charge generated by photoelectric conversion with germanium. Therefore, in a case where the photodiode 29 provided in the first region 27 including germanium and the FD 441 provided in the second region 28 including silicon are irradiated with IR light of the same intensity, the amount of signal charge generated by photoelectric conversion in the FD 441 is sufficiently smaller than the amount of signal charge generated by photoelectric conversion in the photodiode 29.

As described above, in the solid-state imaging device 1 according to the second embodiment, different materials are used for the FD 441 and the photodiode 29. Thereby, the photoelectric conversion in the FD 441 can be suppressed while maintaining the photoelectric conversion in the photodiode 29 using the difference in quantum efficiency of the material. As a result, the influence of PLS can be suppressed.

In addition, in the solid-state imaging device 1 according to the second embodiment, the first region 27 including germanium is present in a region of the first semiconductor layer 21 closer to the light incident surface than the second region 28 in the thickness direction of the first semiconductor layer 21. Therefore, since the IR light incident on the first semiconductor layer 21 from the light incident surface is first absorbed by germanium, the intensity thereof is weakened before reaching the FD 441. As described above, since the first region 27 including germanium absorbs light to play a role of light shielding, photoelectric conversion in the FD 441 can be further suppressed. As a result, the influence of PLS can be further suppressed.

Note that the solid-state imaging device 1 according to the second embodiment of the present technology has a configuration in which the first semiconductor substrate 20 and the second semiconductor substrate 40 are bonded to each other, but as shown in FIG. 14, only the first semiconductor substrate 20 may be included as a substrate. In that case, the reset transistor 45, the selection transistor 46, and the amplification transistor 47 are also provided in the first semiconductor layer 21. Further, the reset transistor 45, the selection transistor 46, and the amplification transistor 47 are provided in the second region 28 of the first semiconductor layer 21.

### Modification Example 1 of Second Embodiment

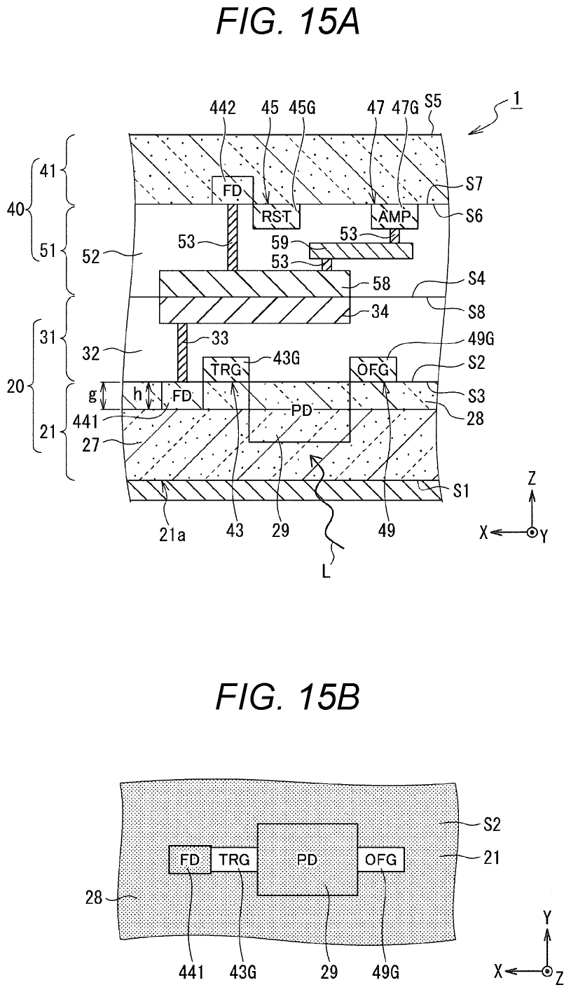

Modification Example 1 of the second embodiment of the present technology shown in FIGS. 15A and 15B will be described below. The solid-state imaging device 1 according to Modification Example 1 of the present second embodiment is different from the solid-state imaging device 1 according to the second embodiment described above in that the second region 28 faces the entire surface of the second surface S2, and is present with the same film thickness in the FD 441 and a part of the photodiode 29, and the other configurations of the solid-state imaging device 1 are basically similar to those of the solid-state imaging device 1 according to the second embodiment described above. Note that the components already described will be denoted by the same reference numerals, and the description thereof will be omitted.

### <Configuration of First Semiconductor Substrate>

### (Configuration of First Semiconductor Layer)

As shown in FIG. 15A, the second region 28 is provided in the first semiconductor layer 21 at a position closer to the second surface S2 in the thickness direction of the first semiconductor layer 21. In addition, as shown in FIG. 15B, the second region 28 faces the entire surface of the second surface S2 which is a surface opposite to the light incident surface among surfaces of the first semiconductor layer 21. That is, the first semiconductor layer 21 has the first region 27 and the second region 28 provided in layers. The film thickness of the second region 28 is uniformly provided in the first semiconductor layer 21. As shown in FIG. 15A, the thickness h, which is the thickness of the FD 441 in the Z direction, is equal to or less than the thickness g, which is the thickness (film thickness) of the second region 28 in the Z direction (h g). In addition, only the first region 27 is provided as a region at a part of the first semiconductor layer 21 closer to the light incident surface than the second region 28 in the thickness direction.

The photodiode 29 is provided in a region including both the first region 27 including germanium and the second region 28 including silicon. That is, the photodiode 29 contains both germanium and silicon. Here, the quantum efficiency of silicon with respect to IR light is lower than that of germanium. However, the photodiode 29 has the first region 27 including germanium at a position closer to the light incident surface and the second region 28 including silicon at a position closer to the second surface S2 opposite to the light incident surface, in the thickness direction of the first semiconductor layer 21. Therefore, the photodiode 29 performs photoelectric conversion mainly in the first region 27. Since the first region 27 is positioned far from the light incident surface side in the photodiode 29, the first region 27 does not greatly contribute to the photoelectric conversion of the photodiode 29. The FD 441 is provided in the second region 28 including silicon. Furthermore, since the second region 28 has a uniform film thickness, the second region 28 is present with the same film thickness in the FD 441 and a part of the photodiode 29.

### <Effect>

Even in the solid-state imaging device 1 according to Modification Example 1 of the second embodiment, the same effects as those of the solid-state imaging device 1 according to the second embodiment described above can be obtained.

Furthermore, in the solid-state imaging device 1 according to Modification Example 1 of the second embodiment, since the second region 28 is uniformly provided in a planar shape, the manufacturing process becomes easy. As a result, mass productivity of the solid-state imaging device 1 can be enhanced.

Furthermore, since the photodiode 29 performs photoelectric conversion using the first region 27 including germanium formed at a position closer to the light incident surface side than the second region 28, a sufficient photoelectric conversion amount can be obtained even when the second region 28 including silicon is included.

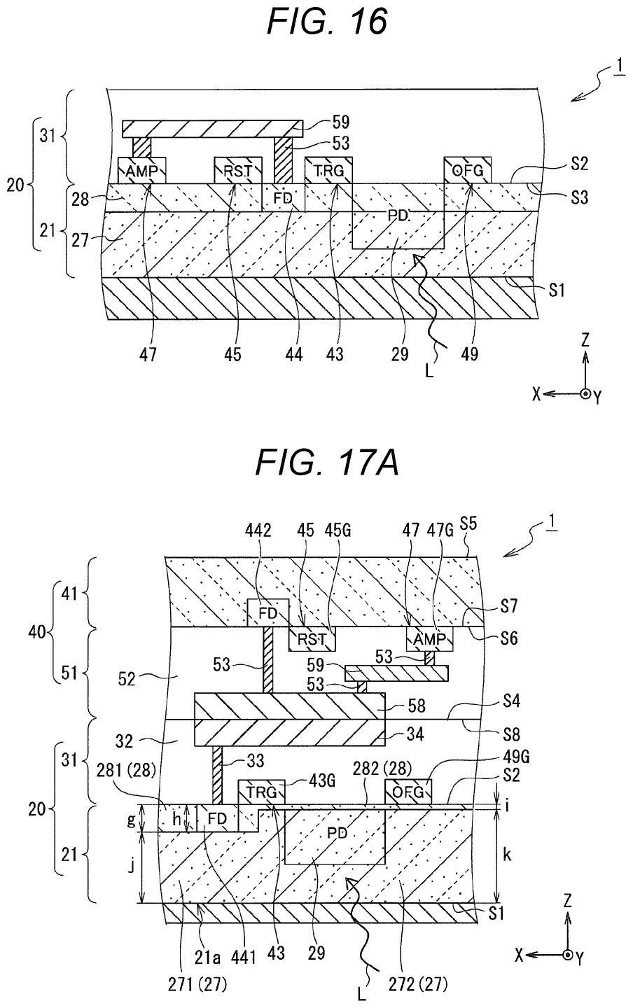

Note that the solid-state imaging device 1 according to Modification Example 1 of the second embodiment of the present technology has a configuration in which the first semiconductor substrate 20 and the second semiconductor substrate 40 are bonded to each other, but as shown in FIG. 16, only the first semiconductor substrate 20 may be included as a substrate.

### Modification Example 2 of Second Embodiment

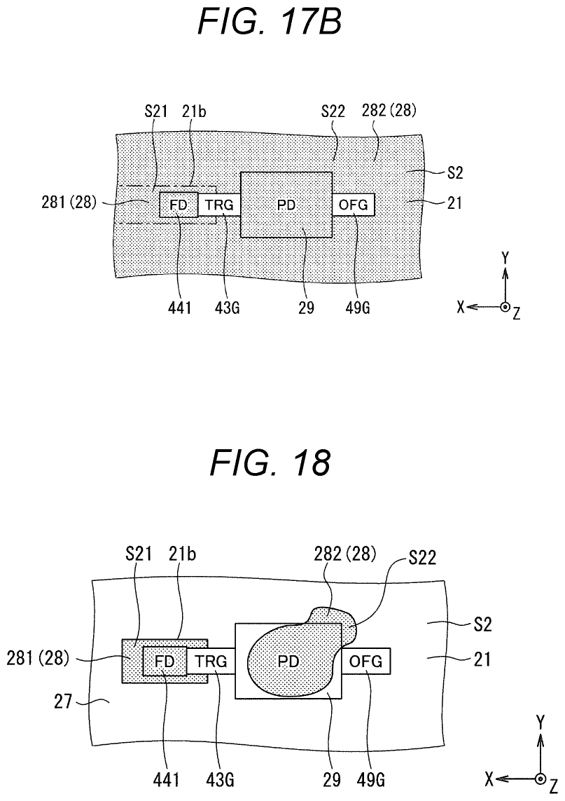

Modification Example 2 of the second embodiment of the present technology shown in FIGS. 17A and 17B will be described below. The solid-state imaging device 1 according to Modification Example 2 of the present second embodiment is different from the solid-state imaging device 1 according to the second embodiment described above in that the second region 28 is provided with a different film thickness with steps, and the other configurations of the solid-state imaging device 1 are basically similar to those of the solid-state imaging device 1 according to the second embodiment described above. Note that the components already described will be denoted by the same reference numerals, and the description thereof will be omitted.

### <Configuration of First Semiconductor Substrate>

### (Configuration of First Semiconductor Layer)

As shown in FIG. 17A, the second region 28 is provided in the first semiconductor layer 21 at a position closer to the second surface S2 in the thickness direction of the first semiconductor layer 21. As shown in FIG. 17B, the second region 28 includes a first part 281 facing the first range S21 that is a part of the second surface S2, and a second part 282 facing a second range S22 that is a part of the second surface S2 different from the first range S21. The first range S21 is a region surrounded by the contour line 21b indicated by an alternate long and short dash line. Here, the second range S22 is the entire partial surface of the second surface S2 other than the first range S21.

As shown in FIG. 17A, the thickness g, which is the thickness (film thickness) of the first part 281 in the Z direction, is larger than the thickness i, which is the thickness (film thickness) of the second part 282 in the Z direction (i<g). As described above, the second region 28 has a configuration in which there is a step between the first part 281 provided with the FD 441 and the other second part 282. The FD 441 is provided at the first part 281 having a large thickness. The thickness h, which is the thickness of the FD 441 in the Z direction, is equal to or less than the thickness g of the first part 281 and is larger than the thickness i of the second part 282 (i<h≤g).

Only the first region 27 is provided as a region at a part of the first semiconductor layer 21 closer to the light incident surface than the second region 28 in the thickness direction. The photodiode 29 is provided in the first region 27. As shown in FIG. 17A, the first region 27 includes a first part 271 provided at a part closer to the light incident surface than the first part 281 in the thickness direction, and a second part 272 provided at a part closer to the light incident surface than the second part 282. The thickness k, which is the thickness (film thickness) of the second part 272 in the Z direction, is larger than the thickness j, which is the thickness (film thickness) of the first part 271 in the Z direction (j<k). The photodiode 29 is provided at the second part 272 having a large thickness.

### <Effect>

Even in the solid-state imaging device 1 according to Modification Example 2 of the second embodiment, the same effects as those of the solid-state imaging device 1 according to the second embodiment described above can be obtained.

Furthermore, in the solid-state imaging device 1 according to Modification Example 2 of the second embodiment, in the second region 28, the second part 282 which is a region other than the first part 281 provided with the FD 441 is provided to be thinner than the first part 281 and the FD 441. As a result, the thickness k of the second part 272 of the first region 27 can be made larger than the thickness j of the first part 271, and the photodiode 29 can be configured only with the first region 27. As a result, since the photodiode 29 is formed not to include a bonding part between different materials such as silicon (second semiconductor material) and germanium (first semiconductor material), the performance of the solid-state imaging device 1 is improved.

Note that the second range S22 is the entire partial surface of the second surface S2 other than the first range S21, but as shown in FIG. 18, the second range S22 may be a part of the second surface S2 other than the first range S21. The second range S22 is only required to be a part of the second surface S2 different from the first range S21.

In addition, the photodiode 29 includes only the first region 27, but may include both the first region 27 including germanium and the second part 282 of the second region 28 including silicon. In this case, although the photodiode 29 contains silicon, the amount of silicon contained in the photodiode 29 is smaller than that in the case of Modification Example 1 of the second embodiment described above. Therefore, the amount of germanium used for photoelectric conversion increases in the photodiode 29, and the performance of the photodiode 29 is improved.

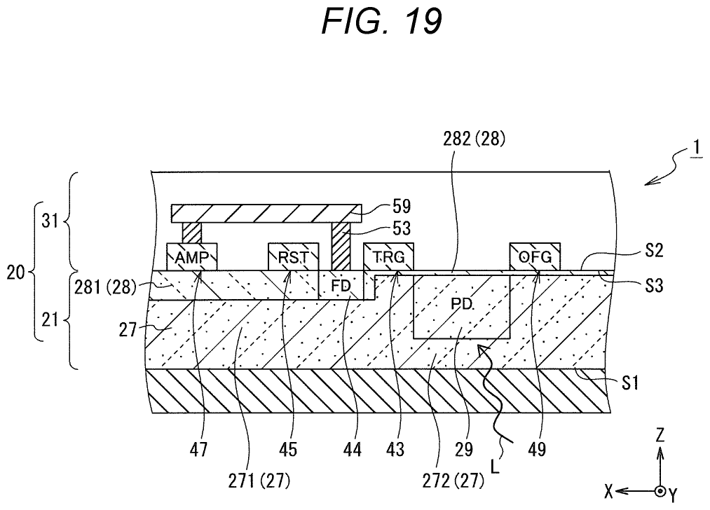

Note that the solid-state imaging device 1 according to Modification Example 2 of the second embodiment of the present technology has a configuration in which the first semiconductor substrate 20 and the second semiconductor substrate 40 are bonded to each other, but as shown in FIG. 19, only the first semiconductor substrate 20 may be included as a substrate.

### Modification Example 3 of Second Embodiment

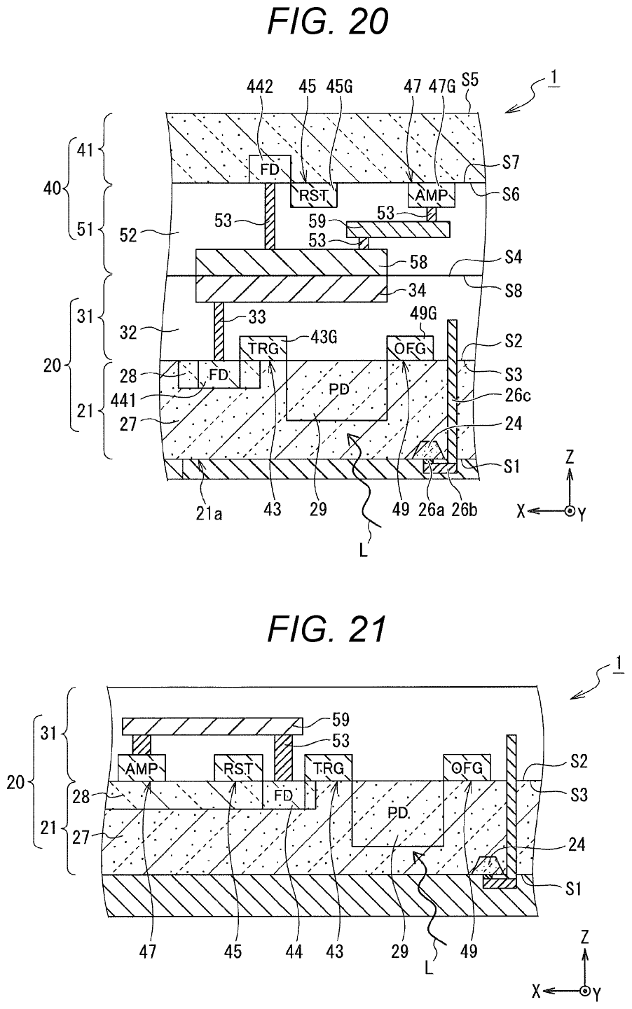

Modification Example 3 of the second embodiment of the present technology shown in FIG. 20 will be described below. The solid-state imaging device 1 according to Modification Example 3 of the present second embodiment is different from the solid-state imaging device 1 according to the second embodiment described above in that the bias voltage VB is applied to the first semiconductor layer 21 from the first surface S1 side in order to assist in pushing out the signal charge generated in the photodiode 29 from the first semiconductor substrate 20 side toward the second semiconductor substrate 40 side, and other configurations of the solid-state imaging device 1 are basically similar to those of the solid-state imaging device 1 according to the second embodiment described above. Note that the components already described will be denoted by the same reference numerals, and the description thereof will be omitted.

The bias voltage VB is applied to the first contact region 24, which is a first conductive type diffusion region, provided in the first semiconductor layer 21. The first contact region 24 is provided in the first semiconductor layer 21 at a position closer to the first surface S1, and more specifically, a part thereof faces the first surface S1. In addition, the bias voltage VB is applied to the first contact region 24 via a via 26a, a wiring 26b, a through-silicon via (TSV) 26c penetrating the first semiconductor layer 21, a wiring (not shown), and the like, which are included in the first semiconductor substrate 20.

### <Effect>

Even in the solid-state imaging device 1 according to Modification Example 3 of the second embodiment, the same effects as those of the solid-state imaging device 1 according to the second embodiment described above can be obtained.

Note that the solid-state imaging device 1 according to Modification Example 3 of the second embodiment of the present technology has a configuration in which the first semiconductor substrate 20 and the second semiconductor substrate 40 are bonded to each other, but as shown in FIG. 21, only the first semiconductor substrate 20 may be included as a substrate.

### Modification Example 4 of Second Embodiment

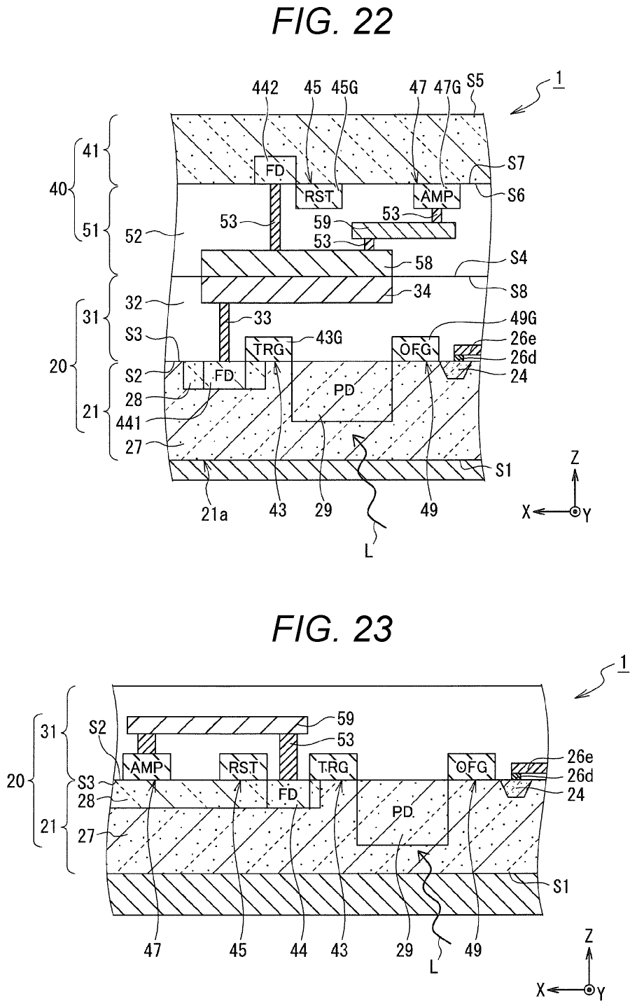

Modification Example 4 of the second embodiment of the present technology shown in FIG. 22 will be described below. The solid-state imaging device 1 according to Modification Example 4 of the present second embodiment is different from the solid-state imaging device 1 according to the second embodiment described above in that the bias voltage VB is applied to the first semiconductor layer 21 from the second surface S2 side in order to assist in pushing out the signal charge generated in the photodiode 29 from the first semiconductor substrate 20 side toward the second semiconductor substrate 40 side, and other configurations of the solid-state imaging device 1 are basically similar to those of the solid-state imaging device 1 according to the second embodiment described above. Note that the components already described will be denoted by the same reference numerals, and the description thereof will be omitted.

The first contact region 24 is provided in the first semiconductor layer 21 at a position closer to the second surface S2, and more specifically, a part thereof faces the second surface S2. In addition, the bias voltage VB is applied to the first contact region 24 via the via 26d, the wiring 26e, and the like of the first semiconductor substrate 20.

### <Effect>

Even in the solid-state imaging device 1 according to Modification Example 4 of the second embodiment, the same effects as those of the solid-state imaging device 1 according to the second embodiment described above can be obtained.

Note that the solid-state imaging device 1 according to Modification Example 4 of the second embodiment of the present technology has a configuration in which the first semiconductor substrate 20 and the second semiconductor substrate 40 are bonded to each other, but as shown in FIG. 23, only the first semiconductor substrate 20 may be included as a substrate.

### Modification Example 5 of Second Embodiment

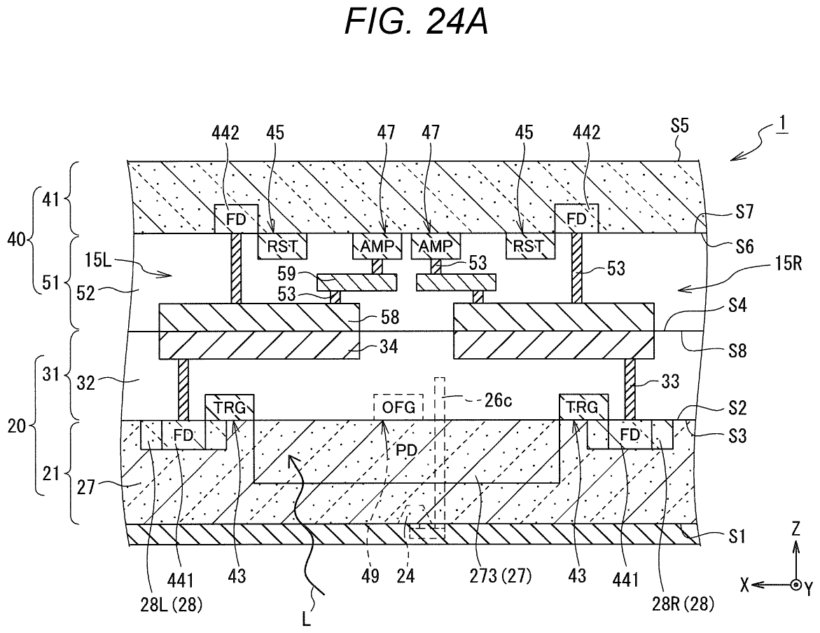

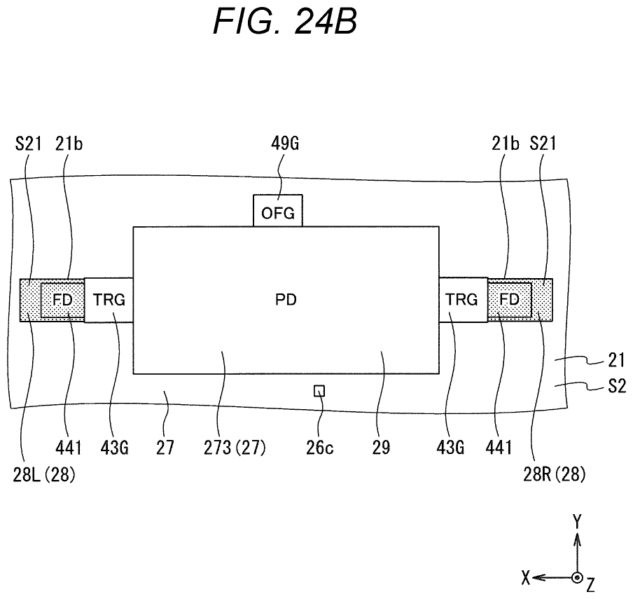

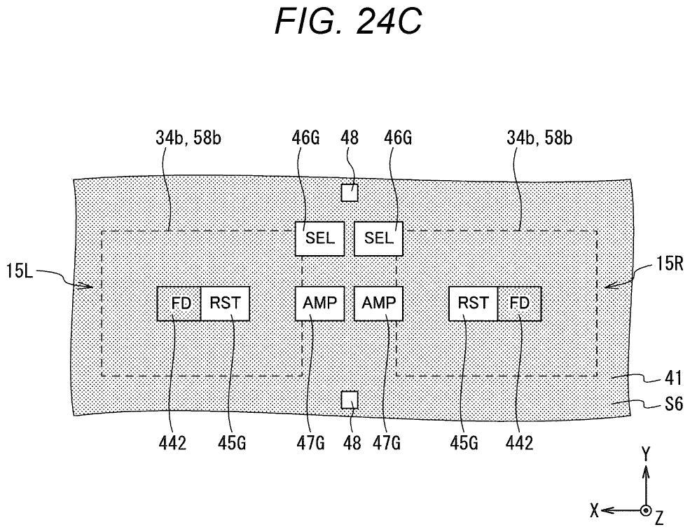

Modification Example 5 of the second embodiment of the present technology shown in FIGS. 24A to 24C will be described below. The solid-state imaging device 1 according to Modification Example 5 of the present second embodiment is obtained by applying the technology according to the second embodiment described above to the solid-state imaging device 1 which is an indirect time of flight (iToF) sensor, and the other configurations of the solid-state imaging device 1 are basically similar to those of the solid-state imaging device 1 according to the second embodiment described above. Note that the components already described will be denoted by the same reference numerals, and the description thereof will be omitted.

Each of the regions 21a of the first semiconductor layer 21 includes the first region 27, a second region 28L, and a second region 28R. In addition, each of the regions 21a of the first semiconductor layer 21 includes one photodiode 29. The photodiode 29 is provided in the first region 27. More specifically, the photodiode 29 is provided at a third part 273 positioned between the second region 28L and the second region 28R in the first region 27.

The solid-state imaging device 1 includes two readout circuits 15L and 15R for one photodiode 29. Each of the readout circuits 15L and 15R reads out the signal charge accumulated in the photodiode 29 and outputs a signal (pixel signal) based on the signal charge. Each of the readout circuits 15L and 15R includes the transfer transistor 43, the FD 441, the FD 442, the reset transistor 45, the selection transistor 46, and the amplification transistor 47. The readout circuits 15L and 15R are provided between the photodiode 29 and the vertical signal line 11 in FIG. 2.

As shown in FIG. 24A, the second region 28L is provided at a position on the readout circuit 15L side in the region 21a, and the second region 28R is provided at a position on the readout circuit 15R side in the region 21a. That is, the second region 28L corresponds to the readout circuit 15L, and the second region 28R corresponds to the readout circuit 15R. The FD 441 of the readout circuit 15L is provided in the second region 28L, and the FD 441 of the readout circuit 15R is provided in the second region 28R. Then, the transfer transistor 43 of the readout circuit 15L transfers the signal charge accumulated in the photodiode 29 to the FD 441 of the readout circuit 15L. Similarly, the transfer transistor 43 of the readout circuit 15R transfers the signal charge accumulated in the photodiode 29 to the FD 441 of the readout circuit 15R. As described above, the solid-state imaging device 1 includes, for each photodiode 29, two sets each including the FD 441, the transfer transistor 43 that transfers the signal charge accumulated in the photodiode 29 to the FD 441, and the second region 28.

The light source device 211 shown in FIG. 29 shines or disappears at a constant cycle when irradiating the subject with light. Then, the solid-state imaging device 1 alternately turns on and off the transfer transistor 43 of the readout circuit 15L and the transfer transistor 43 of the readout circuit 15R at the same cycle as the light source device 211. As a result, the solid-state imaging device 1 distributes and transfers the signal charge obtained by photoelectric conversion by the photodiode 29 to the FD 441 of the readout circuit 15L and the FD 441 of the readout circuit 15R. The distance to the subject is obtained by the ratio of the distributed signal charge.

### <Effect>

Even in the solid-state imaging device 1 according to Modification Example 5 of the second embodiment, the same effects as those of the solid-state imaging device 1 according to the second embodiment described above can be obtained.

Furthermore, even in a case where two readout circuits 15L and 15R are provided for one photodiode 29, the second regions 28 are provided for each of the two readout circuits. Therefore, each FD 441 of the two readout circuits can also be formed in the second region 28.

Note that the number of readout circuits provided for one photodiode 29 is not limited to two, and may be three or more. Similarly, the solid-state imaging device 1 includes, for each photodiode 29, a plurality of sets each including the FD 441, the transfer transistor 43 that transfers the signal charge accumulated in the photodiode 29 to the FD 441, and the second region 28.

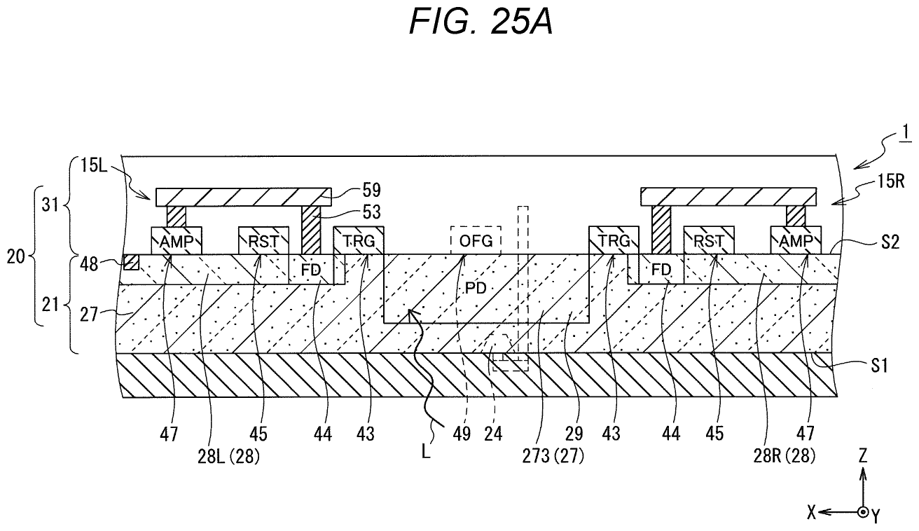

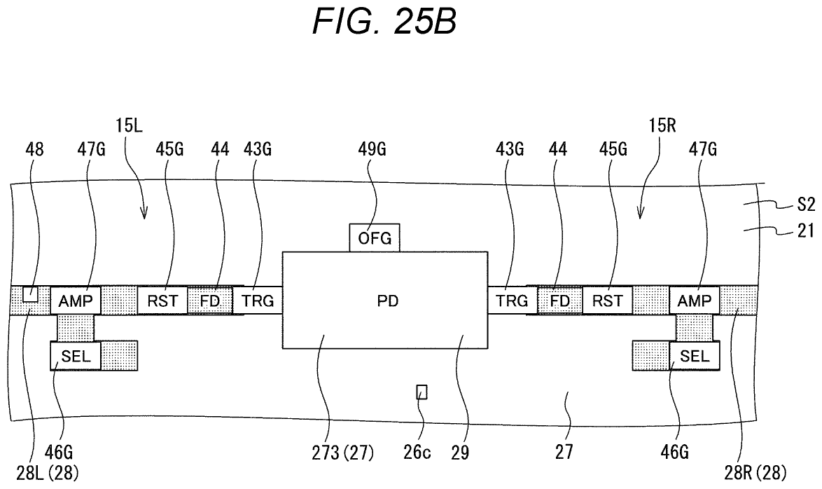

Note that the solid-state imaging device 1 according to Modification Example 5 of the second embodiment of the present technology has a configuration in which the first semiconductor substrate 20 and the second semiconductor substrate 40 are bonded to each other, but as shown in FIGS. 25A and 25B, only the first semiconductor substrate 20 may be included as a substrate.

### Modification Example 6 of Second Embodiment

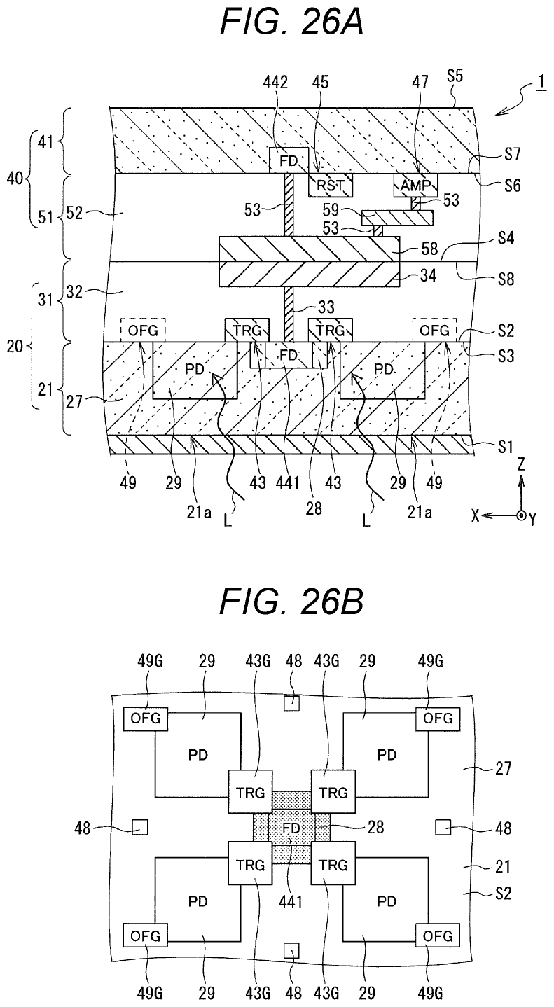

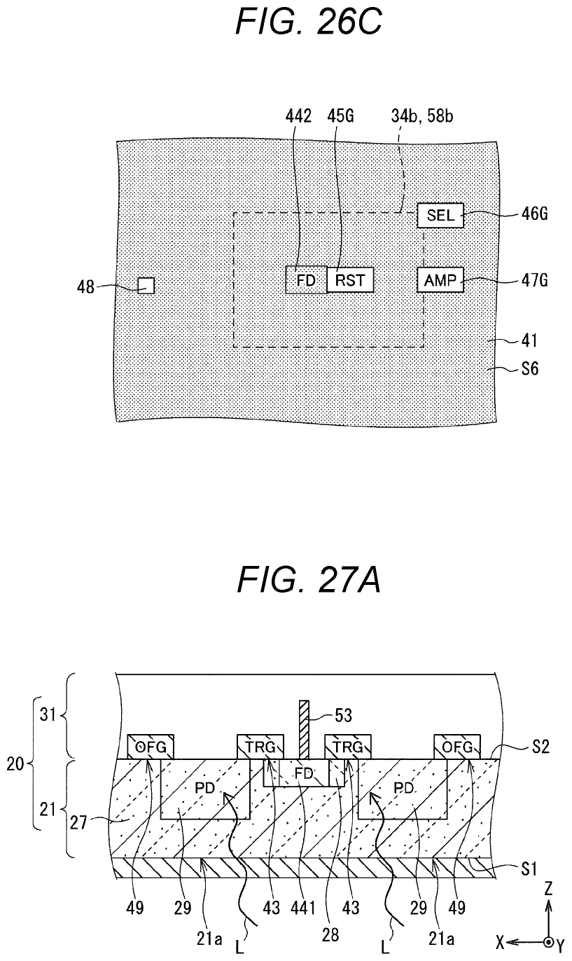

Modification Example 6 of the second embodiment of the present technology shown in FIGS. 26A to 26C will be described below. The solid-state imaging device 1 according to Modification Example 6 of the present second embodiment is different from the solid-state imaging device 1 according to the second embodiment described above in that a pixel sharing structure in which one FD441 is shared by the plurality of photodiodes 29 is provided, and the other configurations of the solid-state imaging device 1 are basically similar to those of the solid-state imaging device 1 according to the second embodiment described above. Note that the components already described will be denoted by the same reference numerals, and the description thereof will be omitted.

FIGS. 26A to 26C show an example in which four photodiodes 29 share one FD 441. Each of the regions 21a includes one photodiode 29 and one transfer transistor 43. The pixel sharing structure is configured with the plurality of photodiodes 29, the plurality of transfer transistors 43, the plurality of discharge transistors 49, one shared FD 441, and other pixel transistors shared one by one (the reset transistor 45, the selection transistor 46, and the amplification transistor 47). That is, in the shared pixels, the photodiode 29 and the transfer transistor 43 that configure a plurality of unit pixels share one FD 44 and other pixel transistors shared one by one. That is, the FD 44 is provided to be able to hold signal charge from the plurality of photodiodes 29, for each of the photodiodes 29.

The FD 441 to be shared is provided in the second region 28. Each of the photodiodes 29 is provided in the first region 27.

### <Effect>

Even in the solid-state imaging device 1 according to Modification Example 6 of the second embodiment, the same effects as those of the solid-state imaging device 1 according to the second embodiment described above can be obtained.

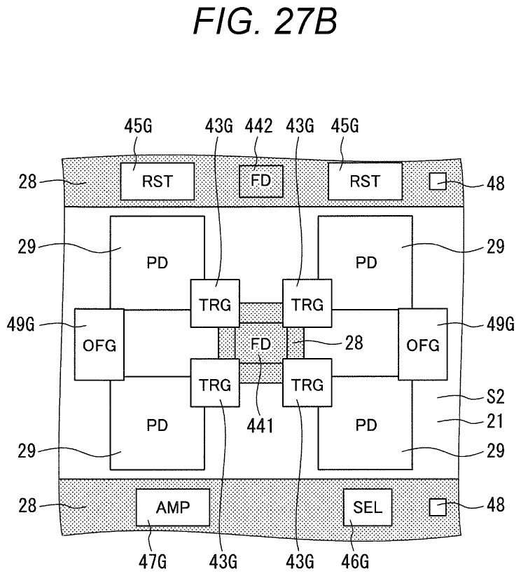

Note that the solid-state imaging device 1 according to Modification Example 6 of the second embodiment of the present technology has a configuration in which the first semiconductor substrate 20 and the second semiconductor substrate 40 are bonded to each other, but as shown in FIGS. 27A and 27B, only the first semiconductor substrate 20 may be included as a substrate.

### Third Embodiment

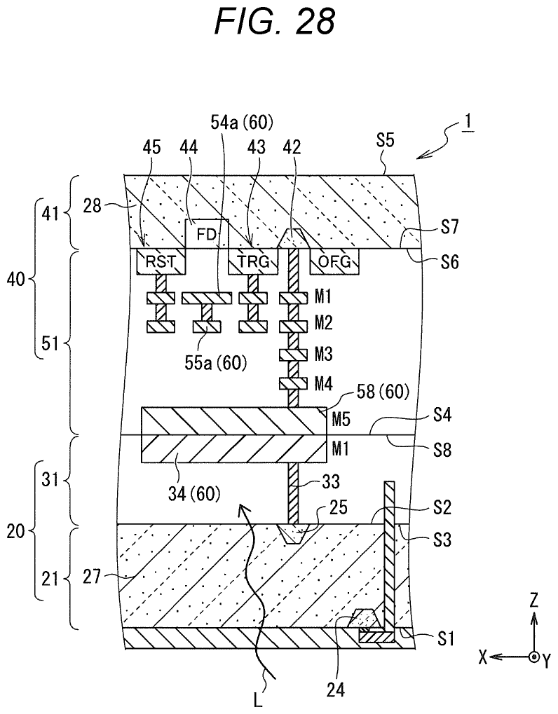

The third embodiment of the present technology shown in FIG. 28 will be described below. The solid-state imaging device 1 according to the present third embodiment is obtained by combining the technology according to the second embodiment described above with the solid-state imaging device 1 according to the first embodiment described above, and the other configurations of the solid-state imaging device 1 are basically similar to those of the solid-state imaging device 1 according to the second embodiment described above. Note that the components already described will be denoted by the same reference numerals, and the description thereof will be omitted.

In the first embodiment described above, a semiconductor substrate including the same material, for example, single crystal silicon is used for the first semiconductor layer 21 and the second semiconductor layer 41. In the present third embodiment, the first semiconductor layer 21 includes a first region 27 including a first semiconductor material, and the second semiconductor layer 41 includes a second region 28 including a second semiconductor material. For example, the first semiconductor layer 21 includes a first semiconductor material (for example, germanium), and the second semiconductor layer 41 includes a second semiconductor material (for example, silicon) of which quantum efficiency is lower than that of the first semiconductor material. The FD 44 is provided in the second region 28. The solid-state imaging device 1 according to the present third embodiment has the same configuration as the solid-state imaging device 1 according to the first embodiment except for the above.

### <Effect>

Even in the solid-state imaging device 1 according to the third embodiment, the same effects as those of the solid-state imaging device 1 according to the first embodiment described above can be obtained.

Furthermore, germanium is more sensitive to the light L such as IR light than silicon. Since there is such a difference in sensitivity, the light L is absorbed when passing through germanium first, and further, the light shielding layer 60 is present, it is possible to suppress a case where the light L reaches the FD 44, and even when the light L can reach the FD 44, photoelectric conversion in silicon can be suppressed due to the difference in sensitivity.

### Fourth Embodiment

In the present fourth embodiment, a configuration example of electronic equipment will be described. As shown in FIG. 29, the distance image equipment 201 as electronic equipment includes an optical system 202, a semiconductor chip (sensor chip) 2X, an image processing circuit 203, a monitor 204, and a memory 205. The distance image equipment 201 may acquire a distance image according to the distance to the subject by receiving light (modulated light or pulsed light) projected from the light source device 211 toward the subject and reflected on a surface of the subject.

The optical system 202 includes one or a plurality of optical lenses, and guides image light from the subject (incident light) to the semiconductor chip 2X to form an image on a light receiving surface (sensor unit) of the semiconductor chip 2X.

As the semiconductor chip 2X, the semiconductor chip 2 on which the solid-state imaging device 1 of the first embodiment described above is mounted is applied, and a distance signal indicating a distance obtained from a light reception signal (APD OUT) output from the semiconductor chip 2X is supplied to the image processing circuit 203.

The image processing circuit 203 performs image processing of constructing the distance image on the basis of the distance signal supplied from the semiconductor chip 2X, and the distance image (image data) obtained by the image processing is supplied to and displayed on the monitor 204, or supplied to and stored (recorded) in the memory 205.

In the distance image equipment 201 configured as described above, by applying the semiconductor chip 2 described above, it is possible to calculate the distance to the subject on the basis of only the light reception signal from the pixel 3 having high stability and to generate a highly accurate distance image. That is, the distance image equipment 201 can acquire a more accurate distance image.

Note that, although the semiconductor chip 2 on which the solid-state imaging device 1 according to the first embodiment of the present technology is mounted is applied as the semiconductor chip 2X, the semiconductor chip 2 on which the solid-state imaging device 1 according to any one of Modification Examples 1 to 3 of the first embodiment, the second embodiment and Modification Examples 1 to 6 thereof, and the third embodiment, or a combination thereof is mounted may be applied.

### <Usage Example of Image Sensor>

The semiconductor chip 2 (image sensor) described above can be used in various cases for sensing light such as visible light, infrared light, ultraviolet light, and X-ray as described below, for example.
A device which takes an image to be used for viewing such as a digital camera and portable equipment with a camera function
A device for traffic purpose such as an in-vehicle sensor which takes images of the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like.
A device for home appliance such as a television, a refrigerator, and an air conditioner that images a user's gesture and performs equipment operation according to the gesture
A device for medical and health care use such as an endoscope and a device that performs angiography by receiving infrared light
A device for security use such as a security monitoring camera and an individual authentication camera
A device for beauty care such as a skin measuring instrument that images skin and a microscope that images scalp
A device for sports use such as an action camera and a wearable camera for sports use and the like
A device used for agriculture, such as a camera for monitoring a condition of a field or crop.

### Other Embodiments

As described above, the present technology is described according to the first to fourth embodiments and modification examples thereof, but it should not be understood that the description and drawings forming a part of this disclosure limit the present technology. Various alternative embodiments, examples, and operation techniques will be apparent to those skilled in the art from this disclosure.

For example, in the second embodiment and the modification examples thereof, the discharge transistor 49 may not be provided. In addition, the configuration of applying the bias voltage VB described in Modification Example 3 and Modification Example 4 of the second embodiment may be applied to the Modification Examples 1, 2, 5, and 6 which are other modification examples of the second embodiment, or may be a configuration that does not apply the bias voltage VB in the second embodiment and the modification examples thereof.

In addition, the technical ideas described in the first to fourth embodiments and the modification examples thereof can be combined with each other. For example, in the solid-state imaging device 1 according to the third embodiment described above, the technical idea of using different semiconductor materials described in the second embodiment described above is combined with the solid-state imaging device 1 according to the first embodiment, but the same idea may be combined with the solid-state imaging devices 1 according to Modification Examples 1 to 3 of the first embodiment. Furthermore, for example, the technical idea of shielding the FD 44 on the second semiconductor substrate 40 side with the light shielding layer 60 described in the first embodiment described above may be combined with the solid-state imaging device 1 according to the second embodiment and Modification Examples 1 to 6 thereof. In addition, for example, the structure of the iToF sensor according to Modification Example 5 of the second embodiment or the structure sharing the FD 441 according to Modification Example 6 of the second embodiment can be applied to Modification Examples 1 to 4 of the second embodiment, and various combinations according to the respective technical ideas are possible.

As described above, it is needless to say that the present technology includes various embodiments and the like that are not described herein. Therefore, the technical scope of the present technology is defined only by the matters specifying the invention described in the claims appropriate from the above description.

Furthermore, the effects described in the present specification are merely examples and are not limited, and other effects may be provided.

It is to be noted that the present technology may also have the following configurations.

(1)

A solid-state imaging device including:
a first semiconductor substrate including a first semiconductor layer provided with a plurality of photoelectric conversion units that performs photoelectric conversion, and a first wiring layer provided on a surface side opposite to a light incident surface of the first semiconductor layer;
a second semiconductor substrate including a second semiconductor layer provided with a charge holding unit that holds signal charge generated in the photoelectric conversion unit and a second wiring layer provided on one surface side of the second semiconductor layer, and overlapped with and bonded to the first semiconductor substrate such that the second wiring layer is positioned between the first wiring layer and the second semiconductor layer; and
a light shielding layer provided in at least one of the first wiring layer or the second wiring layer at a position facing the charge holding unit in a thickness direction.

(2)

The solid-state imaging device according to (1), in which
the light shielding layer overlaps at least a part of the charge holding unit in plan view.

(3)

The solid-state imaging device according to (2), in which
the light shielding layer overlaps the entire charge holding unit in plan view.

(4)

The solid-state imaging device according to any one of (1) to (3), in which
the light shielding layer includes a metal film closest to the second semiconductor layer in a thickness direction of the second wiring layer among a plurality of layers of metal films provided in the second wiring layer.

(5)

The solid-state imaging device according to any one of (1) to (3), in which
the light shielding layer is the metal layer closest to the second semiconductor layer among a plurality of metal layers provided in the second wiring layer at positions facing the charge holding unit in the thickness direction.

(6)

The solid-state imaging device according to any one of (1) to (3), in which
the light shielding layer is at least one connection pad out of a first connection pad provided in the first wiring layer and a second connection pad provided in the second wiring layer and bonded to the first connection pad.

(7)

The solid-state imaging device according to any one of (1) to (3), in which
a plurality of the light shielding layers is provided.

(8)

The solid-state imaging device according to (7), in which
the light shielding layer includes the metal layer closest to the second semiconductor layer in the thickness direction of the second wiring layer among the plurality of metal layers provided in the second wiring layer at positions facing the charge holding unit in the thickness direction, and at least one connection pad out of a first connection pad provided in the first wiring layer and a second connection pad provided in the second wiring layer and bonded to the first connection pad.

(9)

The solid-state imaging device according to any one of (1) to (8), in which
the second semiconductor layer includes a transfer transistor that transfers signal charge obtained by photoelectric conversion to the charge holding unit.

(10)

The solid-state imaging device according to any one of (1) to (9), in which
the first semiconductor layer includes a first semiconductor material, and the second semiconductor layer includes a second semiconductor material having a quantum efficiency, which indicates a probability that photons are converted into electrons, lower than that of the first semiconductor material.

(11)

Electronic equipment including:
a solid-state imaging device; and
an optical system that forms an image of image light from a subject on the solid-state imaging device, in which
the solid-state imaging device includes
a first semiconductor substrate including a first semiconductor layer provided with a plurality of photoelectric conversion units that performs photoelectric conversion, and a first wiring layer provided on a surface side opposite to a light incident surface of the first semiconductor layer,
a second semiconductor substrate including a second semiconductor layer provided with a charge holding unit that holds signal charge generated in the photoelectric conversion unit and a second wiring layer provided on one surface of the second semiconductor layer, and overlapped with and bonded to the first semiconductor substrate such that the second wiring layer is positioned between the first wiring layer and the second semiconductor layer, and
a light shielding layer provided in at least one of the first wiring layer or the second wiring layer at a position facing the charge holding unit in a thickness direction.

(12)

A solid-state imaging device including:
a first semiconductor layer including a first region including a first semiconductor material and a second region including a second semiconductor material of which a quantum efficiency indicating a probability that photons are converted into electrons is lower than that of the first semiconductor material, and including a photoelectric conversion unit that performs photoelectric conversion and a charge holding unit that holds signal charge generated by the photoelectric conversion unit, in which
the photoelectric conversion unit is provided in a region including at least the first region out of the first region and the second region, and
the charge holding unit is provided in the second region.

(13)

The solid-state imaging device according to (12), in which
the second region faces a second surface that is a surface on a side opposite to a light incident surface among surfaces of the first semiconductor layer.

(14)

The solid-state imaging device according to (13), in which
the second region faces the second surface only in a first range that is a part of the second surface.

(15)

The solid-state imaging device according to (13), in which
the second region faces an entire surface of the second surface.

(16)

The solid-state imaging device according to (13), in which
the second region includes a first part facing a first range that is a part of the second surface, and a second part facing a second range that is a part of the second surface different from the first range,
a dimension of the first part in a thickness direction of the first semiconductor layer is larger than a dimension of the second part in the thickness direction of the first semiconductor layer, and
the charge holding unit is provided at the first part.

(17)

The solid-state imaging device according to any one of (12) and (13), in which
each one of the photoelectric conversion units includes a plurality of sets including the charge holding unit, a transfer transistor that transfers the signal charge accumulated in the photoelectric conversion unit to the charge holding unit, and the second region.

(18)

The solid-state imaging device according to any one of (12) to (16), in which
one of the charge holding units is provided to be able to hold the signal charge from a plurality of the photoelectric conversion units, for each of the photoelectric conversion units.

(19)

The solid-state imaging device according to any one of (12) to (18), in which
the first semiconductor material is germanium, silicon germanium, gallium arsenide, indium gallium arsenide, or copper indium gallium selenium, and
the second semiconductor material is silicon.

(20)

Electronic equipment including:
a solid-state imaging device; and
an optical system that forms an image of image light from a subject on the solid-state imaging device, in which
the solid-state imaging device includes
a first semiconductor layer including a first region including a first semiconductor material and a second region including a second semiconductor material of which a quantum efficiency indicating a probability that photons are converted into electrons is lower than that of the first semiconductor material, and including a photoelectric conversion unit that performs photoelectric conversion and a charge holding unit that holds signal charge generated by the photoelectric conversion unit,
the photoelectric conversion unit is provided in a region including at least the first region out of the first region and the second region, and
the charge holding unit is provided in the second region.

The scope of the present technology is not limited to the illustrated and described embodiments, and includes all embodiments that provide effects equivalent to the effects intended to be provided by the present technology. Furthermore, the scope of the present technology is not limited to the combinations of the features of the invention defined by the claims, and may be defined by any desired combination of specific features among all the disclosed features.

### REFERENCE SIGNS LIST

1 Solid-state imaging device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
13 Logic circuit
20 First semiconductor substrate
21 First semiconductor layer
21a Region
22 Separation unit
23 Light absorption unit
24 First contact region
25 Second contact region
27 First region
28 Second region
29 Photodiode
31 First wiring layer
32 First interlayer insulating film
33 Via
34 First connection pad
40 Second semiconductor substrate
41 Second semiconductor layer
42 Third contact region
43 Transfer transistor
44 Floating diffusion
45 Reset transistor
46 Selection transistor
47 Amplification transistor
48 Well contact
49 Discharge transistor
51 Second wiring layer
52 Second interlayer insulating film
53 Via
54, 55, 56, 57 Metal layer
58 Second connection pad
60 Light shielding layer
71 Planarization film
72 Microlens layer
201 Distance image equipment
202 Optical system
2X Semiconductor chip
203 Image processing circuit
204 Monitor
205 Memory
211 Light source device
M1 First metal film
M2 Second metal film
M3 Third metal film
M4 Fourth metal film
M5 Fifth metal film
M6 Sixth metal film

1. A solid-state imaging device comprising:
a first semiconductor substrate including a first semiconductor layer provided with a plurality of photoelectric conversion units that performs photoelectric conversion, and a first wiring layer provided on a surface side opposite to a light incident surface of the first semiconductor layer;
a second semiconductor substrate including a second semiconductor layer provided with a charge holding unit that holds signal charge generated in the photoelectric conversion unit and a second wiring layer provided on one surface side of the second semiconductor layer, and overlapped with and bonded to the first semiconductor substrate such that the second wiring layer is positioned between the first wiring layer and the second semiconductor layer; and
a light shielding layer provided in at least one of the first wiring layer or the second wiring layer at a position facing the charge holding unit in a thickness direction.

2. The solid-state imaging device according to claim 1, wherein
the light shielding layer overlaps at least a part of the charge holding unit in plan view.

3. The solid-state imaging device according to claim 2, wherein
the light shielding layer overlaps the entire charge holding unit in plan view.

4. The solid-state imaging device according to claim 1, wherein
the light shielding layer includes a metal film closest to the second semiconductor layer in a thickness direction of the second wiring layer among a plurality of layers of metal films provided in the second wiring layer.

5. The solid-state imaging device according to claim 1, wherein
the light shielding layer is the metal layer closest to the second semiconductor layer among a plurality of metal layers provided in the second wiring layer at positions facing the charge holding unit in the thickness direction.

6. The solid-state imaging device according to claim 1, wherein
the light shielding layer is at least one connection pad out of a first connection pad provided in the first wiring layer and a second connection pad provided in the second wiring layer and bonded to the first connection pad.

7. The solid-state imaging device according to claim 1, wherein
a plurality of the light shielding layers is provided.

8. The solid-state imaging device according to claim 7, wherein
the light shielding layer includes the metal layer closest to the second semiconductor layer in the thickness direction of the second wiring layer among the plurality of metal layers provided in the second wiring layer at positions facing the charge holding unit in the thickness direction, and at least one connection pad out of a first connection pad provided in the first wiring layer and a second connection pad provided in the second wiring layer and bonded to the first connection pad.

9. The solid-state imaging device according to claim 1, wherein
the second semiconductor layer includes a transfer transistor that transfers signal charge obtained by photoelectric conversion to the charge holding unit.

10. The solid-state imaging device according to claim 1, wherein
the first semiconductor layer includes a first semiconductor material, and the second semiconductor layer includes a second semiconductor material having a quantum efficiency, which indicates a probability that photons are converted into electrons, lower than that of the first semiconductor material.

11. Electronic equipment comprising:
a solid-state imaging device; and
an optical system that forms an image of image light from a subject on the solid-state imaging device, wherein
the solid-state imaging device includes
a first semiconductor substrate including a first semiconductor layer provided with a plurality of photoelectric conversion units that performs photoelectric conversion, and a first wiring layer provided on a surface side opposite to a light incident surface of the first semiconductor layer,
a second semiconductor substrate including a second semiconductor layer provided with a charge holding unit that holds signal charge generated in the photoelectric conversion unit and a second wiring layer provided on one surface of the second semiconductor layer, and overlapped with and bonded to the first semiconductor substrate such that the second wiring layer is positioned between the first wiring layer and the second semiconductor layer, and
a light shielding layer provided in at least one of the first wiring layer or the second wiring layer at a position facing the charge holding unit in a thickness direction.

12. A solid-state imaging device comprising:
a first semiconductor layer including a first region including a first semiconductor material and a second region including a second semiconductor material of which a quantum efficiency indicating a probability that photons are converted into electrons is lower than that of the first semiconductor material, and including a photoelectric conversion unit that performs photoelectric conversion and a charge holding unit that holds signal charge generated by the photoelectric conversion unit, wherein
the photoelectric conversion unit is provided in a region including at least the first region out of the first region and the second region, and
the charge holding unit is provided in the second region.

13. The solid-state imaging device according to claim 12, wherein
the second region faces a second surface that is a surface on a side opposite to a light incident surface among surfaces of the first semiconductor layer.

14. The solid-state imaging device according to claim 13, wherein
the second region faces the second surface only in a first range that is a part of the second surface.

15. The solid-state imaging device according to claim 13, wherein
the second region faces an entire surface of the second surface.

16. The solid-state imaging device according to claim 13, wherein
the second region includes a first part facing a first range that is a part of the second surface, and a second part facing a second range that is a part of the second surface different from the first range,
a dimension of the first part in a thickness direction of the first semiconductor layer is larger than a dimension of the second part in the thickness direction of the first semiconductor layer, and
the charge holding unit is provided at the first part.

17. The solid-state imaging device according to claim 12, wherein
each one of the photoelectric conversion units includes a plurality of sets including the charge holding unit, a transfer transistor that transfers the signal charge accumulated in the photoelectric conversion unit to the charge holding unit, and the second region.

18. The solid-state imaging device according to claim 12, wherein
one of the charge holding units is provided to be able to hold the signal charge from a plurality of the photoelectric conversion units, for each of the photoelectric conversion units.

19. The solid-state imaging device according to claim 12, wherein
the first semiconductor material is germanium, silicon germanium, gallium arsenide, indium gallium arsenide, or copper indium gallium selenium, and
the second semiconductor material is silicon.

20. Electronic equipment comprising:
a solid-state imaging device; and
an optical system that forms an image of image light from a subject on the solid-state imaging device, wherein
the solid-state imaging device includes
a first semiconductor layer including a first region including a first semiconductor material and a second region including a second semiconductor material of which a quantum efficiency indicating a probability that photons are converted into electrons is lower than that of the first semiconductor material, and including a photoelectric conversion unit that performs photoelectric conversion and a charge holding unit that holds signal charge generated by the photoelectric conversion unit,
the photoelectric conversion unit is provided in a region including at least the first region out of the first region and the second region, and
the charge holding unit is provided in the second region.
